(19) United States
(12) Patent Application Publication
(10) Pub. No.: US 2026/0105962 A1
(43) Pub. Date: Apr. 16, 2026

(54) NON-VOLATILE MEMORY DEVICE, OPERATION METHOD THEREOF, AND ELECTRONIC SYSTEM INCLUDING THE SAME

(71) Applicant: Samsung Electronics Co., Ltd., Suwon-si (KR)

(72) Inventors: Seonhong Min, Suwon-si (KR); Sang-Won Shim, Suwon-si (KR); Jeil Ryu, Suwon-si (KR)

(21) Appl. No.: 19/305,282

(22) Filed: Aug. 20, 2025

(30) Foreign Application Priority Data
Oct. 15, 2024 (KR) 10-2024-0140481

(51) Int. Cl. G11C 16/08; G11C 16/32

(52) U.S. Cl. CPC G11C 16/08; G11C 16/32

(57) ABSTRACT

An operation method of an unselected read voltage generator included in a non-volatile memory device includes applying a first voltage to a first word line group and a second word line group of unselected word lines among a plurality of word lines connected to a plurality of memory cells during a first time, floating the first word line group and applying a second voltage to the second word line group during a second time, and floating the second word line group and applying the first voltage to the first word line group during a third time. The unselected read voltage generator includes one voltage regulator that generates the first voltage based on a first reference voltage and generates the second voltage based on a second reference voltage.

### CROSS-REFERENCE TO RELATED APPLICATION

This application claims priority under 35 U.S.C. § 119 to Korean Patent Application No. 10-2024-0140481 filed on Oct. 15, 2024, in the Korean Intellectual Property Office, the entirety of which is incorporated by reference herein.

### BACKGROUND

A non-volatile memory device may perform a data write operation or a data read operation, based on a plurality of voltages. For example, the non-volatile memory device may read data of memory cells connected to a selected word line by applying a read voltage to the selected word line and a read pass voltage to the remaining word lines. The non-volatile memory device may include a voltage generator which generates a plurality of voltages.

The voltage generator may include a plurality of voltage regulators which generate the plurality of voltages. When the voltage generator includes multiple voltage generators, there may occur issues such as an increase in the area of a circuit and an increase in the amount of power consumption.

### SUMMARY

Implementations of the present disclosure provide non-volatile memory devices including a voltage regulator capable of generating a plurality of read pass voltages based on one voltage regulator.

According to some implementations, an operation method of an unselected read voltage generator included in a non-volatile memory device includes applying a first voltage to a first word line group and a second word line group of unselected word lines among a plurality of word lines connected to a plurality of memory cells during a first time, floating the first word line group and applying a second voltage to the second word line group during a second time, and floating the second word line group and applying the first voltage to the first word line group during a third time. The unselected read voltage generator includes one voltage regulator that generates the first voltage based on a first reference voltage and generates the second voltage based on a second reference voltage.

According to some implementations, a non-volatile memory device includes a memory cell array that is connected to a plurality of word lines and stores data, and an unselected read voltage generator that includes one voltage regulator generating a switch input voltage including a first voltage and a second voltage and applies a voltage to unselected word lines among the plurality of word lines. During a first time, the unselected read voltage generator applies the first voltage to the unselected word lines. During a second time, the unselected read voltage generator floats a first word line group of the unselected word lines and applies the second voltage to a second word line group of the unselected word lines. During a third time, the unselected read voltage generator floats the second word line group and apply the first voltage to the first word line group.

According to some implementations, a non-volatile memory device includes a memory cell array that is connected to a plurality of word lines and stores data, and an unselected read voltage generator that includes one voltage regulator generating a switch input voltage including a first voltage and a second voltage and applies a voltage to unselected word lines among the plurality of word lines. During a first time, the unselected read voltage generator applies a first voltage to a first word line group of the unselected word lines and floats a second word line group of the unselected word lines. During a second time, the unselected read voltage generator floats the first word line group and applies a second voltage to the second word line group. The one voltage regulator generates the first voltage based on a first reference voltage and generates the second voltage based on a second reference voltage.

According to some implementations, an operation method of an unselected read voltage generator included in a non-volatile memory device includes applying a first voltage to a first word line group of unselected word lines among a plurality of word lines connected to a plurality of memory cells and floating a second word line group of the unselected word lines during a first time and floating the first word line group and applying a second voltage to the second word line group during a second time. The unselected read voltage generator includes one voltage regulator that generates the first voltage based on a first reference voltage and generates the second voltage based on a second reference voltage.

### BRIEF DESCRIPTION OF THE FIGURES

The above and other objects and features of the present disclosure will become apparent by describing in detail examples thereof with reference to the accompanying drawings.

FIG. 1 is a block diagram illustrating an example of a non-volatile memory device.

FIG. 2 is a circuit diagram illustrating an example of one block of FIG. 1.

FIG. 3 is a graph illustrating threshold voltage distributions of memory cells of FIG. 2, according to some implementations of the present disclosure.

FIG. 4 is a block diagram illustrating examples of word line groups of one memory block of FIGS. 1 and 2.

FIG. 5 is a block diagram illustrating an example of an unselected read voltage generator of FIG. 1.

FIG. 6 is a block diagram illustrating an example of a switch circuit of FIG. 5.

FIG. 7 is a flowchart illustrating an example of an operation method of an unselected read voltage generator.

FIG. 8 is a timing diagram illustrating an example of an operation of an unselected read voltage generator of FIGS. 5 and 6.

FIG. 9 is a flowchart illustrating an example of an operation method of an unselected read voltage generator.

FIG. 10 is a timing diagram illustrating an example of an operation of an unselected read voltage generator of FIGS. 5 and 6 over time, according to some implementations of the present disclosure.

FIG. 11 is a block diagram illustrating an example of a host storage system.

FIG. 12 is a diagram illustrating an example of a memory device, according to some implementations of the present disclosure.

### DETAILED DESCRIPTION

In the detailed description, components which are described with reference to the terms “unit”, “module”, “block”, “circuit”, “circuitry”, etc. and function blocks which are illustrated in drawings, will be implemented in the form of software or hardware or in the form of a combination thereof. For example, the software may include a machine code, firmware, an embedded code, and/or application software. For example, the hardware may include an electrical circuit, an electronic circuit (e.g., an analog circuit or a digital circuit), a processor, a computer, an integrated circuit, integrated circuit cores, a pressure sensor, an inertial sensor, a microelectromechanical system (MEMS), a passive element, or a combination thereof.

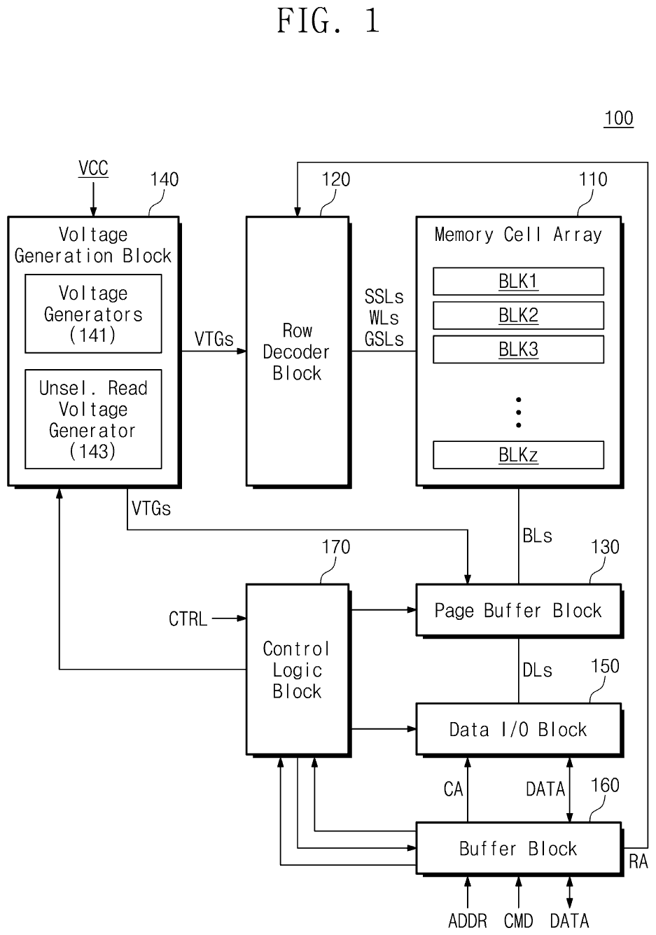

FIG. 1 is a block diagram illustrating a non-volatile memory device in detail, according to some implementations of the present disclosure. Referring to FIG. 1, a non-volatile memory device 100 may include a memory cell array 110, a row decoder block 120, a page buffer block 130, a voltage generation block 140, a data input/output (I/O) block 150, a buffer block 160, and a control logic block 170. In some implementations, the non-volatile memory device 100 may include memory cells of an arbitrary structure. For example, the non-volatile memory device 100 may include NAND flash memory cells. Below, for convenience, the description will be given based on the case where the non-volatile memory device 100 is a NAND flash memory device, but the scope and spirit of the present disclosure is not limited thereto. For example, it should be understood that some implementations in which the non-volatile memory device 100 includes any other type of memory cells such as a ferro-electric random access memory (FeRAM) cell, a magnetic RAM (MRAM) cell, or a spin torque transfer MRAM (STTMRAM) cell also belong to the scope and spirit of the present disclosure.

The memory cell array 110 includes a plurality of memory blocks BLK1 to BLKz. Each of the memory blocks BLK1 to BLKz may include a plurality of memory cells. Each of the memory blocks BLK1 to BLKz may be connected to the row decoder block 120 through at least one ground selection line GSL, word lines WLs, and at least one string selection line SSL. Some of the word lines WL may be used as a dummy word line. Each of the memory blocks BLK1 to BLKz may be connected to the page buffer block 130 through a plurality of bit lines BLs. The plurality of memory blocks BLK1 to BLKz may be connected in common to the plurality of bit lines BLs.

In some implementations, each of the plurality of memory blocks BLK1 to BLKz may be a unit of an erase operation. The memory cells belonging to each of the memory blocks BLK1 to BLKz may be simultaneously erased. In some implementations, each of the plurality of memory blocks BLK1 to BLKz may be divided into sub-blocks. Each of the plurality of sub-blocks may be a unit of the erase operation, and a plurality of memory cells belonging to each sub-block may be simultaneously erased. Below, the erase unit may indicate the unit of the erase operation, and the erase unit may correspond to a memory block or a sub-block.

Each of the memory blocks BLK1 to BLKz may include a plurality of pages. The plurality of pages may be respectively connected to the word lines WLs. Each of the pages may be a unit of the write operation.

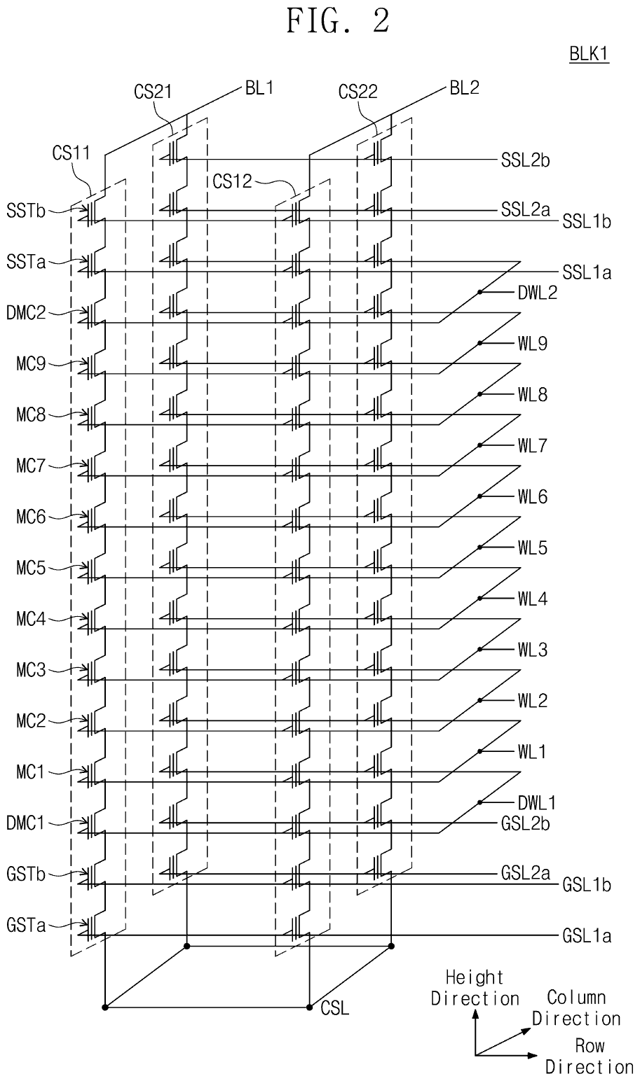

Bits which are written in memory cells of one page may constitute or form logical pages. For example, when three bits are written in one memory cell, one physical page may include three logical pages. For another example, when one bit is written in one memory cell, one physical page may include one logical page. The logical page(s) or the physical page may be a unit of the read operation. The memory blocks BLK1 to BLKz will be described in detail with reference to FIG. 2.

The row decoder block 120 may decode a row address RA received from the buffer block 160 and may control voltages to be applied to the string selection lines SSLs, the word lines WLs, and the ground selection lines GSLs based on the decoded row address RA.

The page buffer block 130 may be connected to the memory cell array 110 through the plurality of bit lines BLs. The page buffer block 130 may be connected to the data input/output block 150 through a plurality of data lines DLs. The page buffer block 130 may operate under control of the control logic block 170.

When the non-volatile memory device 100 performs the program operation, the page buffer block 130 may store data to be written in memory cells. The page buffer block 130 may apply a corresponding voltage to each of the plurality of bit lines BLs, based on the data stored therein. When the non-volatile memory device 100 performs the read operation or performs a verifying read operation of the program operation or the erase operation, the page buffer block 130 may sense a voltage of each of the bit lines BLs and may store a sensing result.

The voltage generation block 140 may generate various voltages used for the operation of the non-volatile memory device 100. In some implementations, the voltage generation block 140 may generate a plurality of voltages, based on a power supply voltage VCC. For example, the voltage generation block 140 may convert or process the power supply voltage VCC to generate voltages VTGs and may transfer the generated voltages VTGs to the row decoder block 120 or the page buffer block 130.

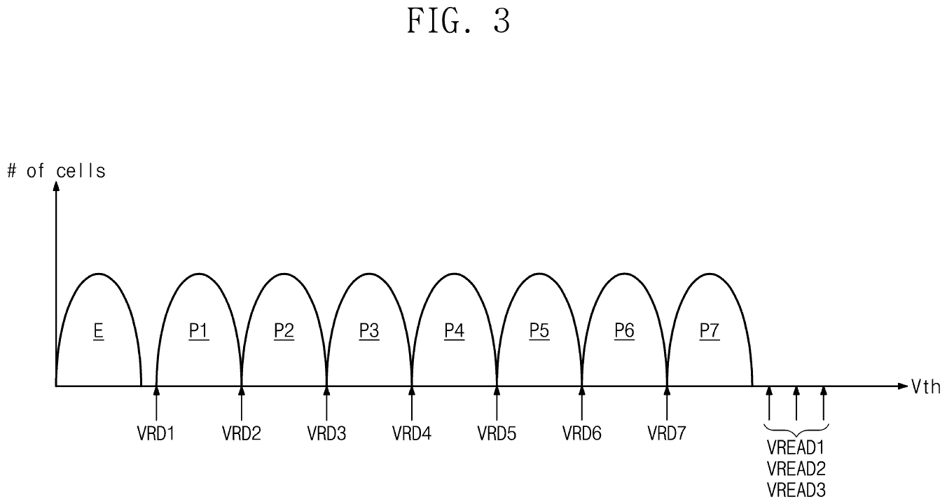

In some implementations, the voltage generation block 140 may operate under control of the control logic block 170. Referring to FIG. 1, the voltage generation block 140 may include voltage generators 141 and an unselected read (Unsel. Read) voltage generator 143. An example of voltages which the voltage generation block 140 generates will be described in detail with reference to FIG. 3.

The voltage generators 141 may generate various voltages necessary for the operation of the non-volatile memory device 100. In some implementations, the voltage generators 141 may generate voltages necessary for the read operation or the write operation. For example, the voltage generators 141 may generate voltages to be provided to the string selection lines SSLs or the ground selection lines GSLs, selected read voltages, program voltages, or erase voltages to be provided to the word lines WLs, or one or more voltages to be provided to a page buffer. The voltage generators 141 may transfer the generated voltages to the row decoder block 120 or the page buffer block 130.

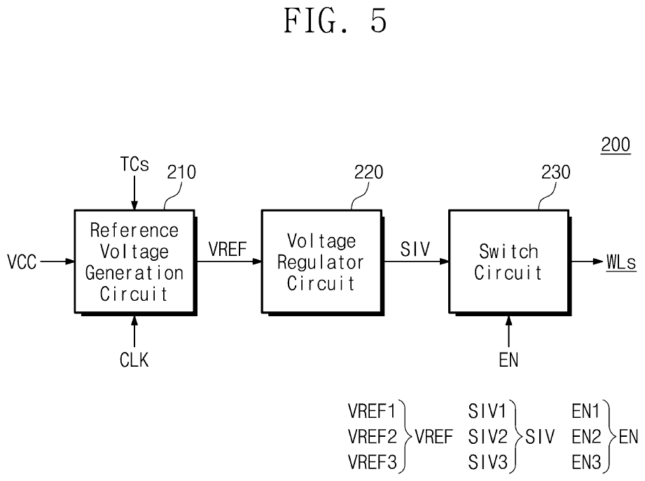

The unselected read voltage generator 143 may generate a voltage(s) to be provided to unselected word lines during the read operation of the non-volatile memory device 100. In some implementations, the unselected read voltage generator unit 143 may include only one voltage regulator. The unselected read voltage generator 143 may include only one voltage regulator, and thus, the area of circuit may be reduced compared to the case where the unselected read voltage generator 143 includes a plurality of voltage regulators respectively corresponding to a plurality of voltages. The unselected read voltage generator 143 will be described in detail with reference to FIGS. 5 to 11.

The voltage generators 141 and the unselected read voltage generator 143 may be distinguished from each other depending on functions, and the scope and spirit of the present disclosure is not limited to the example illustrated in FIG. 1. For example, it should be understood that some implementations in which the voltage generators 141 include the unselected read voltage generator 143 also belong to the scope and spirit of the present disclosure. It should be understood that the voltage generators 141 may be identical or similar in configuration or operation to the unselected read voltage generator 143 to be described with reference to FIGS. 5 to 11. For example, the voltage generators 141 may include one or more voltage generators capable of receiving a plurality of reference voltages.

The data input/output block 150 may be connected to the page buffer block 130 through the plurality of data lines DLs. The data input/output block 150 may receive a column address CA from the buffer block 160. The data input/output block 150 may output the data read by the page buffer block 130 to the buffer block 160 depending on the column address CA. The data input/output block 150 may transfer the data received from the buffer block 160 to the page buffer block 130, based on the column address CA.

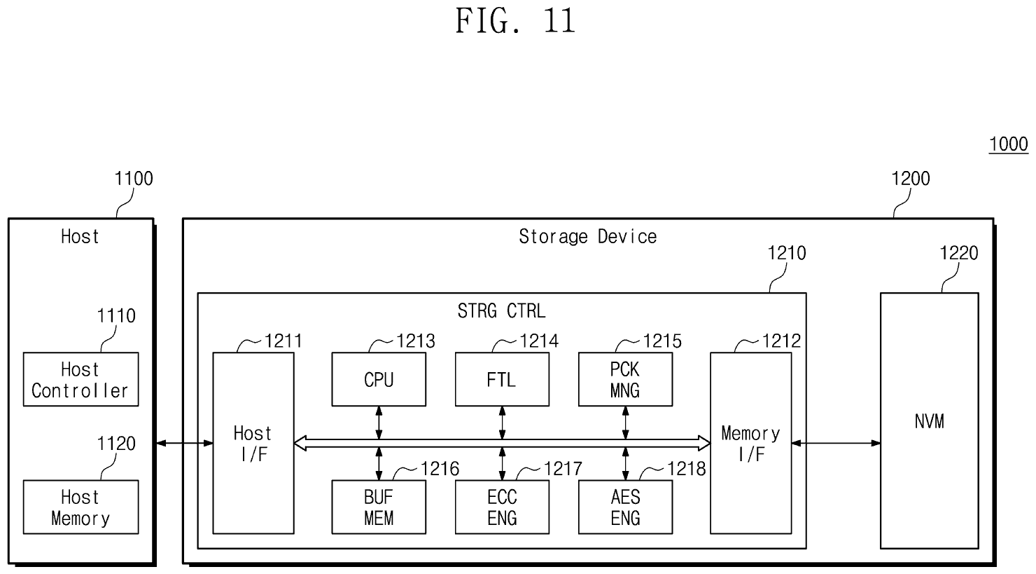

The buffer block 160 may receive a command CMD or an address value ADDR from an external device (e.g., a storage controller 1210 (refer to FIG. 11)) and may exchange data “DATA” with the external device. The buffer block 160 may operate under control of the control logic block 170. The buffer block 160 may transfer the command CMD to the control logic block 170, may transfer the row address RA of the address value ADDR to the row decoder block 120, and may transfer the column address CA of the address value ADDR to the data input/output block 150. The buffer block 160 may exchange the data “DATA” with the data input/output block 150.

The control logic block 170 may receive a control signal CTRL through the external device (e.g., the storage controller 1210). The control logic block 170 may allow the buffer block 160 to route the command CMD, the address value ADDR, and the data “DATA”. The control logic block 170 may decode the command CMD received from the buffer block 160 and may control the non-volatile memory device 100 based on the decoded command.

In some implementations, the non-volatile memory device 100 may be manufactured in a bonding method. The memory cell array 110 may be manufactured by using a first wafer, and the row decoder block 120, the page buffer block 130, the voltage generation block 140, the data input/output block 150, the buffer block 160, and the control logic block 170 may be manufactured by using a second wafer. The non-volatile memory device 100 may be implemented by coupling the first wafer and the second wafer such that an upper surface of the first wafer and an upper surface of the second wafer face each other.

In some implementations, the non-volatile memory device 100 may be manufactured in a cell over peri (COP) method. A peripheral circuit including the row decoder block 120, the page buffer block 130, the voltage generation block 140, the data input/output block 150, the buffer block 160, and the control logic block 170 may be implemented on a substrate. The memory cell array 110 may be implemented over the peripheral circuit. The peripheral circuit and the memory cell array 110 may be connected by using the through vias.

FIG. 2 is a circuit diagram illustrating a first memory block among a plurality of memory blocks included in a memory cell array of FIG. 1. In some implementations, the non-volatile memory device 100 of FIG. 1 may be a flash memory device including a plurality of memory blocks.

A memory block of a three-dimensional structure will be described with reference to FIG. 2, but the memory block is not limited thereto. A memory block according to the present disclosure may have a two-dimensional memory block structure. A first memory block BLK1 will be described with reference to FIG. 2, but the memory block is not limited thereto. The remaining memory blocks may be similar in structure to the first memory block BLK1 to be described with reference to FIG. 2.

In some implementations, the first memory block BLK1 to be described with reference to FIG. 2 may correspond to a physical erase unit of the non-volatile memory device 100. However, the erase unit is not limited thereto. For example, an erase unit may be changed to a page unit, a word line unit, a sub-block unit, etc.

Referring to FIG. 2, the first memory block BLK1 may include a plurality of cell strings CS11, CS12, CS21, and CS22. The plurality of cell strings CS11, CS12, CS21, and CS22 may be arranged in a row direction and a column direction to form rows and columns.

Each of the plurality of cell strings CS11, CS12, CS21, and CS22 includes a plurality of cell transistors. For example, each of the plurality of cell strings CS11, CS12, CS21, and CS22 may include string selection transistors SSTa and SSTb, a plurality of memory cells MC1 to MC9, ground selection transistors GSTa and GSTb, and dummy memory cells DMC1 and DMC2. In some implementations, each of a plurality of cell transistors included in the cell strings CS11, CS12, CS21, and CS22 may be a charge trap flash (CTF) memory cell.

In each cell string, the plurality of memory cells MC1 to MC9 are serially connected and are stacked in a direction perpendicular to a plane defined by the row direction and the column direction, that is, in a height direction. In each cell string, the string selection transistors SSTa and SSTb are serially connected and are interposed between a bit line BL1 or BL2 and the plurality of memory cells MC1 to MC9, and the ground selection transistors GSTa and GSTb are serially connected. The serially-connected ground selection transistors GSTa and GSTb are provided between the plurality of memory cells MC1 to MC9 and a common source line CSL.

In some implementations, in each cell string, the first dummy memory cell DMC1 may be provided between the plurality of memory cells MC1 to MC9 and the ground selection transistors GSTa and GSTb. In some implementations, in each cell string, the second dummy memory cell DMC2 may be provided between the plurality of memory cells MC1 to MC9 and the string selection transistors SSTa and SSTb.

The ground selection transistors GSTa of the cell strings CS11, CS12, CS21, and CS22 may be connected in common with a common source line CSL. In some implementations, ground selection transistors in the same row may be connected to the same ground selection line, and ground selection transistors in different rows may be connected to different ground selection lines. For example, the first ground selection transistors GSTa of the cell strings CS11 and CS12 in the first row may be connected to a first ground selection line, and the first ground selection transistors GSTa of the cell strings CS21 and CS22 in the second row may be connected to a second ground selection line.

In some implementations, ground selection transistors provided at the same height from a substrate may be connected to the same ground selection line, and ground selection transistors provided at different heights therefrom may be connected to different ground selection lines.

Memory cells of the same height from the substrate or the ground selection transistors GSTa and GSTb are connected in common to the same word line, and memory cells of different heights therefrom are connected to different word lines. For example, the memory cells MC1 to MC9 of the cell strings CS11, CS12, CS21, and CS22 may be connected to first to ninth word lines WL1 to WL9.

String selection transistors, which belong to the same row, from among the first string selection transistors SSTa of the same height are connected to the same string selection line, and string selection transistors, which belong to another row, from among the first string selection transistors SSTa are connected to another string selection line. For example, the first string selection transistors SSTa of the cell strings CS11 and CS12 in the first row may be connected in common to a string selection line SSL1a, and the first string selection transistors SSTa of the cell strings CS21 and CS22 in the second row may be connected in common to a string selection line SSL2a.

Likewise, string selection transistors, which belong to the same row, from among the second string selection transistors SSTb at the same height are connected to the same string selection line, and string selection transistors, which belong to another row, from among the second string selection transistors SSTb are connected to another string selection line. For example, the second selection transistors SSTb of the cell strings CS11 and CS12 in the first row are connected in common to a string selection line SSL1b, and the second string selection transistors SSTb of the cell strings CS21 and CS22 in the second row are connected in common to a string selection line SSL2b.

In some implementations, dummy memory cells of the same height are connected to the same dummy word line, and dummy memory cells of different heights are connected with different dummy word lines. For example, the first dummy memory cells DMC1 are connected to a first dummy word line DWL1, and the second dummy memory cells DMC2 are connected to a second dummy word line DWL2.

The first memory block BLK1 illustrated in FIG. 2 is provided only as an example. The number of cell strings may increase or decrease, and the number of rows of cell strings and the number of columns of cell strings may increase or decrease depending on the number of cell strings. Also, the number of cell transistors GST, MC, DMC, and SST of the first memory block BLK1 may increase or decrease, and the height of the first memory block BLK1 may increase or decrease depending on the number of cell transistors. In addition, the number of lines GSL, WL, DWL, and SSL connected to the cell transistors may increase or decrease depending on the number of cell transistors.

FIG. 3 is a threshold voltage distribution diagram of memory cells of FIG. 2. Below, for clarity of description, it is assumed that each of the memory cells of the non-volatile memory device 100 is a triple level cell (TLC) configured to store 3-bit data. However, the cell type is not limited thereto. For example, each memory cell may be a single level cell (SLC) storing 1-bit data, or a multi-level cell (MLC), a triple level cell (TLC), or a quad level cell (QLC) storing n-bit data (n being a natural number more than 1).

Referring to FIGS. 2 and 3, each memory cell may be programmed to have one of an erase state “E” and first to seventh program states P1 to P7. To read data programmed in the memory cells, the non-volatile memory device 100 may use a plurality of selected read voltages VRD1 to VRD7 and a plurality of unselected read voltages VREAD1 to VREAD3. For example, to read data programmed in memory cells connected to a selected word line, the non-volatile memory device 100 may sequentially apply at least one of the plurality of selected read voltages VRD1 to VRD7 to the selected word line and may apply each of the plurality of unselected read voltages VREAD1 to VREAD3 to unselected word lines.

In some implementations, the plurality of selected read voltages VRD1 to VRD7 may be levels for distinguishing the erase state “E” and the first to seventh program states P1 to P7. The plurality of unselected read voltages VREAD1 to VREAD3 may be levels higher than the erase state “E” and the first to seventh program states P1 to P7. For example, memory cells connected to an unselected word line to which the plurality of unselected read voltages VREAD1 to VREAD3 are applied may be in a turn-on state, e.g., based on levels of the unselected read voltages VREAD1 to VREAD3. In some implementations, a level of an unselected read voltage required for each word line may vary depending on physical characteristics of memory cells or physical locations of memory cells. For example, the plurality of unselected read voltages VREAD1 to VREAD3 may have different levels.

A plurality of voltage regulators may be used to generate the plurality of unselected read voltages VREAD1 to VREAD3. For example, “n” voltage regulators may be used to generate “n” unselected read voltages. In this case, the area or power consumption of each of the plurality of voltage regulator (or the area or power consumption of a voltage source corresponding to each of the plurality of voltage regulators) may disadvantageously increase.

The non-volatile memory device 100 according to some implementations of the present disclosure may use “k” voltage regulators to generate the “n” unselected read voltages; in some implementations, “n” and “k” may be positive integers, and “k” may be less than “n”. For example, the non-volatile memory device 100 may use one voltage regulator to generate the “n” unselected read voltages, where “n” is two or more. The non-volatile memory device 100 of the present disclosure may include voltage regulators, the number of which is less than the number of unselected read voltages to be generated, and thus, the area or power consumption of a configuration generating unselected read voltages may decrease.

Three unselected read voltages VREAD1 to VREAD3 are illustrated for clarity of description, but the number of unselected read voltages is not limited thereto. For example, the number of unselected read voltages (i.e., the number of different levels) may be variously changed and modified. Below, the description will be given based on the case where the non-volatile memory device 100 includes one voltage regulator and includes a voltage generator (e.g., the unselected read voltage generator 143 of FIG. 1) capable of generating a plurality of unselected read voltages, but the number of voltage regulators is not limited thereto. For example, it should be understood that the description provided for the following drawings is identically or similarly applicable to a voltage generator including voltage regulators, the number of which is less than the number of unselected read voltages to be generated.

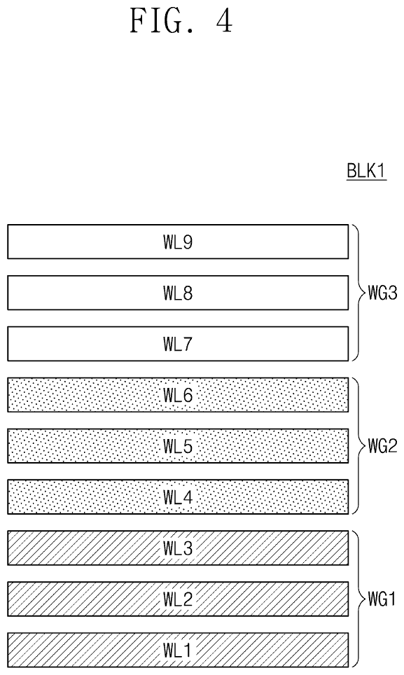

FIG. 4 is a diagram for describing word lines included in a first memory block of FIG. 2. Referring to FIGS. 2 to 4, the first memory block BLK1 may include the first to ninth word lines WL1 to WL9. The first to ninth word lines WL1 to WL9 may be classified into first to third word line groups WG1, WG2, and WG3. For example, the first word line group WG1 may include the first to third word lines WL1 to WL3, the second word line group WG2 may include the fourth to sixth word lines WL4 to WL6, and the third word line group WG3 may include the seventh to ninth word lines WL7 to WL9.

In the read operation, the non-volatile memory device 100 may control unselected word lines in units of group. For example, the non-volatile memory device 100 may apply one of the selected read voltages VRD1 to VRD7 of FIG. 3 to a selected word line and may apply the unselected read voltages VREAD1 to VREAD3 to unselected word lines for respective word line groups WG1 to WG3.

In detail, for example, when the fifth word line WL5 is a selected word line, the selected read voltages VRD1 to VRD7 may be applied to the fifth word line WL5, and the first unselected read voltage VREAD1 may be applied to the first to third word lines WL1 to WL3 belonging to the first word line group WG1 from among the unselected word lines. In this case, the second unselected read voltage VREAD2 may be applied to the fourth word line WL4 and the sixth word line WL6 being unselected word lines from among the word lines WL4 to WL6 of the second word line group WG2, and the third unselected read voltage VREAD3 may be applied to the seventh to ninth word lines WL7 to WL9 of the third word line group WG3. For example, a level of an unselected read voltage to be applied may vary depending on a physical location of the unselected word line or a word line group.

The first memory block BLK1, the first to ninth word lines WL1 to WL9, the first to third word line groups WG1 to WG3, the selected read voltage VRD, the number of unselected read voltages VREAD1 to VREAD3, and the levels of the unselected read voltages VREAD1 to VREAD3, which are described with reference to FIG. 4, are provided as an example, and the configuration of word lines and read voltages is not limited thereto. The number of word line groups and the number of word lines included in a word line group may increase or decrease. In FIG. 4, the description is given based on the case where each word line group includes an identical number of word lines, but the number of word lines is not limited thereto. For example, at least some of word line groups may include different numbers of word lines. Below, the description will be given based on the case where the unselected read voltages VREAD1, VREAD2, and VREAD3 respectively corresponding to the word line groups WG1, WG2, and WG3 are applied, but it should be understood that, in some implementations, the unselected read voltages VREAD1, VREAD2, and VREAD3 are not applied to the selected word line (the selected read voltages VRD1 to VRD7 may be applied to the selected word line).

FIG. 5 is a block diagram illustrating an unselected read voltage generator of FIG. 1 in detail, according to some implementations of the present disclosure. An unselected read voltage generator 200 may correspond to the unselected read voltage generator 143 of FIG. 1. Referring to FIG. 5, the unselected read voltage generator 200 may include a reference voltage generation circuit 210, a voltage regulator circuit 220, and a switch circuit 230.

The reference voltage generation circuit 210 may generate a plurality of reference voltages VREF1 to VREF3 (collectively referred to as “VREF”). For example, the reference voltage generation circuit 210 may generate the first reference voltage VREF1 having a first reference voltage level, the second reference voltage VREF2 having a second reference voltage level, and the third reference voltage VREF3 having a third reference voltage level.

In some implementations, the reference voltage generation circuit 210 may output one of the plurality of reference voltages VREF. For example, when the reference voltage generation circuit 210 outputs the first reference voltage VREF1, the reference voltage generation circuit 210 may not output the second reference voltage VREF2 and the third reference voltage VREF3. In some implementations, the reference voltage generation circuit 210 may generate the plurality of reference voltages VREF, based on the power supply voltage VCC.

In some implementations, the reference voltage generation circuit 210 may generate the plurality of reference voltages VREF in response to one or more signals. For example, the reference voltage generation circuit 210 may receive trimcodes TCs and may generate the plurality of reference voltages VREF respectively corresponding to the trimcodes TCs. Herein, the trimcodes TCs may respectively indicate levels of the plurality of reference voltages VREF, and each of the trimcodes TCs may be a code having a plurality of bits. In some implementations, the number of trimcodes TCs which the reference voltage generation circuit 210 receives may be equal to the number of reference voltages VREF which the reference voltage generation circuit 210 generates. For example, when the reference voltage generation circuit 210 generates the first to third reference voltages VREF1 to VREF3, the reference voltage generation circuit 210 may receive three trimcodes TCs.

In some implementations, the reference voltage generation circuit 210 may generate the plurality of reference voltages VREF further in response to a clock signal CLK. For example, the reference voltage generation circuit 210 may generate the first to third reference voltages VREF1 to VREF3, based on the trimcodes TCs and the clock signal CLK. In some implementations, in response to the clock signal CLK, the reference voltage generation circuit 210 may select one reference voltage to be output from among the plurality of reference voltages VREF or may change a reference voltage to be output from among the plurality of reference voltages VREF. In some implementations, the reference voltage generation circuit 210 may accumulate the clock signal CLK, and, based on a magnitude(s) of the accumulated clock signal CLK, the reference voltage generation circuit 210 may generate one of the first to third reference voltages VREF1 to VREF3 or may select or change one reference voltage to be output from among the first to third reference voltages VREF1 to VREF3. For example, in response to the clock signal CLK or the accumulation of the clock signal CLK, the reference voltage generation circuit 210 may sequentially output the first reference voltage VREF1, the second reference voltage VREF2, and the third reference voltage VREF3. For example, the reference voltage generation circuit 210 may sequentially output the first reference voltage VREF1, the second reference voltage VREF2, and the third reference voltage VREF3 based on elapse of time as indicated by the clock signal CLK or accumulation thereof.

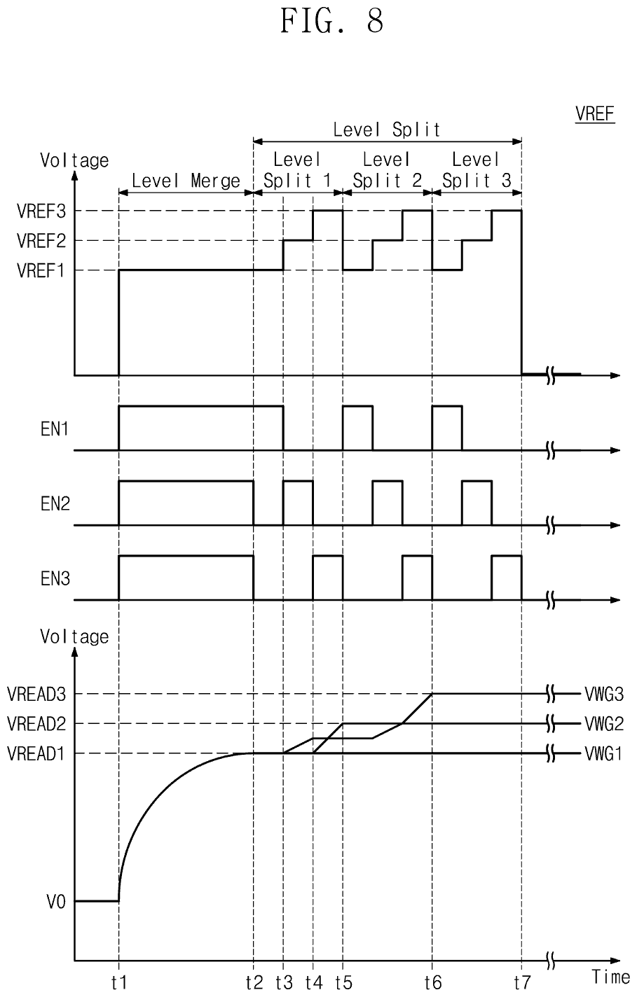

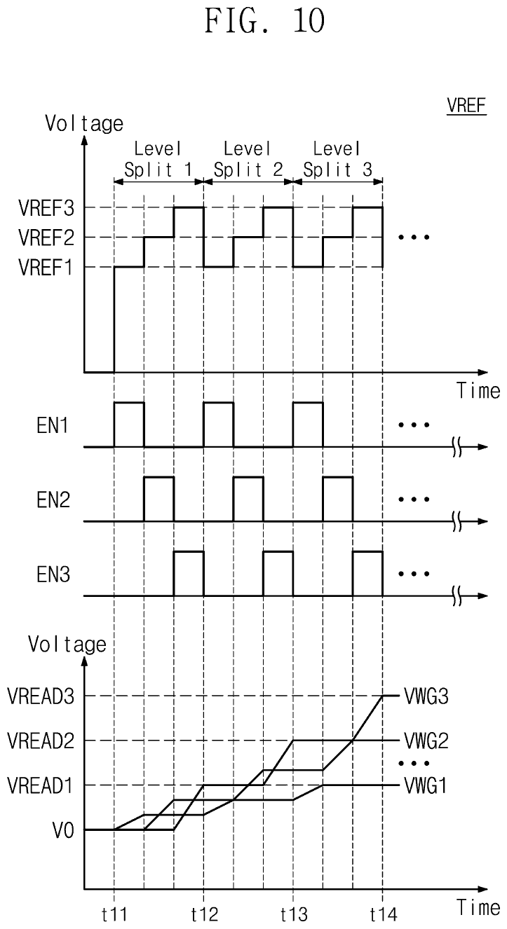

FIG. 5 shows the case where the reference voltage generation circuit 210 sequentially outputs the first to third reference voltages VREF1 to VREF3, but the output of the reference voltages is not limited thereto. For example, it should be understood that some implementations in which the first to third reference voltages VREF1 to VREF3 are output in a reverse order or some implementations in which the first to third reference voltages VREF1 to VREF3 are output in an arbitrary order also belong to the scope and spirit of the present disclosure. An example of the plurality of reference voltages VREF which the reference voltage generation circuit 210 generates will be described in detail with reference to FIGS. 8 and 10.

The voltage regulator circuit 220 may receive the plurality of reference voltages VREF and may perform a voltage regulate operation. In some implementations, the voltage regulator circuit 220 may generate switch input voltages SIV1 to SIV3 (collectively referred to as “SIV”) corresponding to the plurality of reference voltages VREF. For example, the voltage regulator circuit 220 may generate the first switch input voltage SIV1 corresponding to the first reference voltage VREF1, the second switch input voltage SIV2 corresponding to the second reference voltage VREF2, and the third switch input voltage SIV3 corresponding to the third reference voltage VREF3.

In some implementations, the voltage regulator circuit 220 may include one voltage regulator or may be one voltage regulator. For example, the voltage regulator circuit 220 may be a low-dropout (LDO) regulator which receives the plurality of reference voltages VREF as an input and outputs the switch input voltage SIV or may include the LDO regulator.

In some implementations, the switch input voltage SIV may be equal in magnitude to the unselected read voltage. In some implementations, the magnitude of the switch input voltage SIV may correspond to the magnitude of the unselected read voltage. For example, referring to FIG. 3 together, the first switch input voltage SIV1 may correspond to the first unselected read voltage VREAD1 or may be identical to the first unselected read voltage VREAD1, the second switch input voltage SIV2 may correspond to the second unselected read voltage VREAD2 or may be identical to the second unselected read voltage VREAD2, and the third switch input voltage SIV3 may correspond to the third unselected read voltage VREAD3 or may be equal to the third unselected read voltage VREAD3.

In some implementations, the voltage regulator circuit 220 may output one of the switch input voltages SIV1, SIV2, and SIV3. For example, when the voltage regulator circuit 220 outputs the first switch input voltage SIV1, the voltage regulator circuit 220 may not output the second switch input voltage SIV2 and the third switch input voltage SIV3. The voltage regulator circuit 220 may provide the generated switch input voltage SIV to the switch circuit 230.

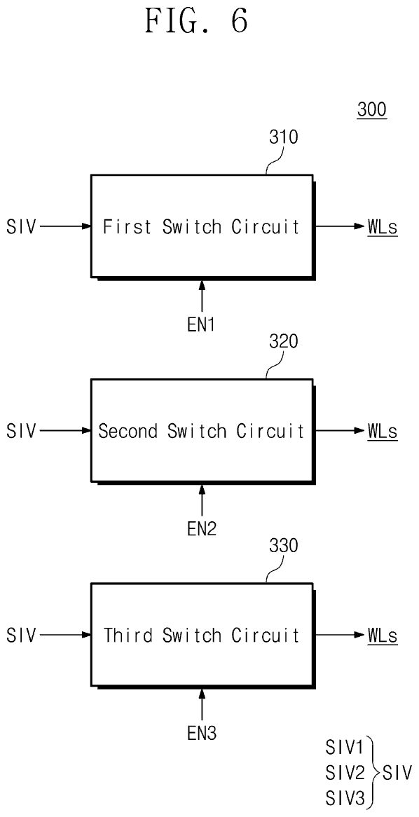

The switch circuit 230 may receive the switch input voltage SIV and may select word lines to which the switch input voltage SIV will be provided. In some implementations, in response to enable signals EN1 to EN3 (collectively referred to as “EN”), the switch circuit 230 may select word lines to which the switch input voltage SIV will be provided or may change word lines to which the switch input voltage SIV will be provided. For example, in response to the enable signals EN, the switch circuit 230 may select one or more of word line groups (e.g., the first to third word line groups WG1 to WG3 of FIG. 4) to which the switch input voltage SIV will be provided. Based on an operation of selecting word line groups to which a voltage will be applied, the switch circuit 230 may simultaneously increase or pull up voltage levels of word line groups or may independently (or separately) increase or pull up the voltage levels of the word line groups. The switch circuit 230 will be described in detail with reference to FIG. 6.

In FIG. 5, the description is given based on the case where each of the number of reference voltages VREF1, VREF2, and VREF3, the number of switch input voltages SIV1, SIV2, and SIV3, and the number of enable signals EN1, EN2, and EN3 is three, but the number of voltages and signals is not limited thereto. In some implementations, each of the number of reference voltages, the number of switch input voltages, and the number of enable signals may have any other value(s). In FIG. 5, the description is given based on the case where all of the number of reference voltages VREF1, VREF2, and VREF3, the number of switch input voltages SIV1, SIV2, and SIV3, and the number of enable signals EN1, EN2, and EN3 are equal, but the number of voltages and signals is not limited thereto. In some implementations, at least some of the number of reference voltages, the number of switch input voltages, and the number of enable signals may be different.

FIG. 6 is a block diagram illustrating a switch circuit of FIG. 5 in detail, according to some implementations of the present disclosure. A switch circuit 300 may correspond to the switch circuit 230 of FIG. 5. Referring to FIG. 6, the switch circuit 300 may include a first switch circuit 310, a second switch circuit 320, and a third switch circuit 330.

The first switch circuit 310 may provide or may not provide the switch input voltage SIV to a first group of word lines. In some implementations, the first switch circuit 310 may be turned on or turned off in response to the first enable signal EN1; when the first switch circuit 310 is turned on, the first switch circuit 310 may provide the switch input voltage SIV to the first group of word lines. For example, in response to the first enable signal EN1 being at the high level, the first switch circuit 310 may provide the switch input voltage SIV to the first word line group WG1 of FIG. 4. In this case, the level of the first word line group WG1 may be increased or pulled up based on the switch input voltage SIV.

The second switch circuit 320 may provide or may not provide the switch input voltage SIV to a second group of word lines. In some implementations, the second switch circuit 320 may be turned on or turned off in response to the second enable signal EN2; when the second switch circuit 320 is turned on, the second switch circuit 320 may provide the switch input voltage SIV to the second group of word lines. For example, in response to the second enable signal EN2 being at the high level, the second switch circuit 320 may provide the switch input voltage SIV to the second word line group WG2 of FIG. 4. In this case, the level of the second word line group WG2 may be increased or pulled up based on the switch input voltage SIV.

The third switch circuit 330 may provide or may not provide the switch input voltage SIV to a third group of word lines. In some implementations, the third switch circuit 330 may be turned on or turned off in response to the third enable signal EN3; when the third switch circuit 330 is turned on, the third switch circuit 330 may provide the switch input voltage SIV to the third group of word lines. For example, in response to the third enable signal EN3 being at the high level, the third switch circuit 330 may provide the switch input voltage SIV to the third word line group WG3 of FIG. 4. In this case, the level of the third word line group WG3 may be increased or pulled up based on the switch input voltage SIV.

The description is given based on the case where when each of the switch circuits 310, 320, and 330 is turned on, each of the switch circuits 310, 320, and 330 provides the switch input voltage SIV directly to the corresponding word line group, but the voltage provision is not limited thereto. For example, voltages according to operations of the switch circuits 310, 320, and 330 may be transferred to the word line groups through the row decoder block 120 of FIG. 1.

How the switch circuits 310, 320, and 330 operate in response to the enable signals EN1, EN2, and EN3 will be described with reference to FIGS. 8 and 10. In FIG. 6, the description is given based on the case where each of the switch circuits 310, 320, and 330 operates in response to the corresponding one of the enable signals EN1, EN2, and EN3 being at the high level, but the operation is not limited thereto. In some implementations, each of at least some of the switch circuits 310, 320, and 330 may operate in response to the corresponding one of the enable signals EN1, EN2, and EN3 being at the low level. In FIG. 6, the correspondence between the word line groups WG1, WG2, and WG3 to which the switch circuits 310, 320, and 330 transfer the switch input voltages SIV is provided as an example, but the configuration thereof is not limited thereto. In FIG. 6, the description is given based on the case where the number of switch circuits is three, but the number of switch circuits is not limited thereto.

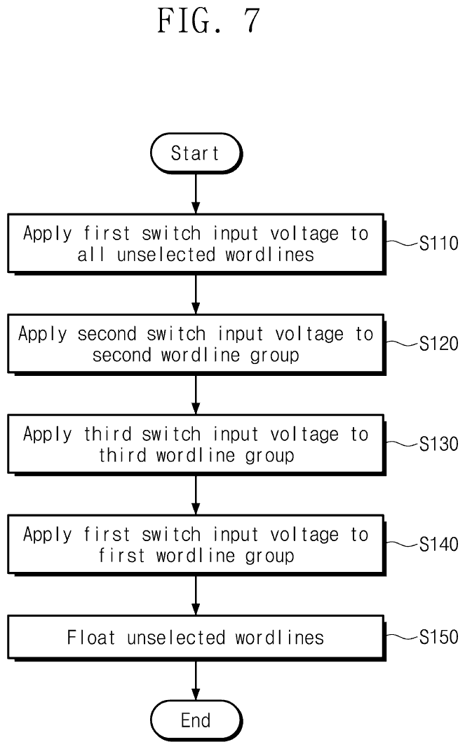

FIG. 7 is a flowchart illustrating an operation method of an unselected read voltage generator of FIGS. 5 and 6, according to some implementations of the present disclosure. The operation method of the unselected read voltage generator 200 of FIGS. 5 and 6 will be described in detail with reference to FIGS. 1 to 7. Below, the description will be given based on the case where the unselected read voltage generator 200 applies the switch input voltages SIV to the word line groups WG1, WG2, and WG3, but it should be understood that unselected read voltages may not be applied to a selected word line among word lines included in the word line groups WG1, WG2, and WG3.

The first switch input voltage SIV1 may be equal to the first unselected read voltage VREAD1 or may correspond to the first unselected read voltage VREAD1. The second switch input voltage SIV2 may be equal to the second unselected read voltage VREAD2 or may correspond to the second unselected read voltage VREAD2. The third switch input voltage SIV3 may be equal to the third unselected read voltage VREAD3 or may correspond to the third unselected read voltage VREAD3. The above correspondence relationship is provided as an example, and the scope and spirit of the present disclosure is not limited thereto.

Referring to FIG. 7, in operation S110, the unselected read voltage generator 200 may apply the first switch input voltage SIV1 to each of unselected word lines. In some implementations, the unselected read voltage generator 200 may change all the enable signals EN1, EN2, and EN3 to the high level such that the first switch input voltage SIV1 increases or pulls up the voltage levels of the word line groups WG1, WG2, and WG3.

In operation S120, the unselected read voltage generator 200 may apply the second switch input voltage SIV2 to the second word line group WG2. In some implementations, the unselected read voltage generator 200 may maintain the second enable signal EN2 at the high level and may change the first enable signal EN1 and the third enable signal EN3 to the low level. In this case, the first word line group WG1 and the third word line group WG3 may be floated. The voltage level of the second word line group WG2 may be increased or pulled up based on operation S120. For example, the voltage level of the second word line group WG2 may be increased or pulled up in response to operation S120 such that the voltage level of the second word line group WG2 reaches the second unselected read voltage VREAD2.

In operation S130, the unselected read voltage generator 200 may apply the third switch input voltage SIV3 to the third word line group WG3. In some implementations, the unselected read voltage generator 200 may change the second enable signal EN2 to the low level, may maintain the first enable signal EN1 at the low level, and may change the third enable signal EN3 to the high level. In this case, the first word line group WG1 and the second word line group WG2 may be floated. The voltage level of the third word line group WG3 may be increased or pulled up based on operation S130. For example, the voltage level of the third word line group WG3 may be increased or pulled up in response to operation S130 such that the voltage level of the third word line group WG3 reaches the third unselected read voltage VREAD3.

In operation S140, the unselected read voltage generator 200 may apply the first switch input voltage SIV1 to the first word line group WG1. In some implementations, the unselected read voltage generator 200 may change the third enable signal EN3 to the low level, may maintain the second enable signal EN2 at the low level, and may change the first enable signal EN1 to the high level. In this case, the second word line group WG2 and the third word line group WG3 may be floated. The voltage level of the first word line group WG1 may be increased or pulled up based on operation S140. For example, the voltage level of the first word line group WG1 may be increased or pulled up in response to operation S140 such that the voltage level of the first word line group WG1 reaches the first unselected read voltage VREAD1.

In operation S150, the unselected read voltage generator 200 may float unselected word lines. In some implementations, the unselected read voltage generator 200 may change all the enable signals EN1, EN2, and EN3 to the low level such that the unselected word lines are floated. For example, as the word line groups WG1, WG2, and WG3 are floated, the unselected read voltages VREAD1, VREAD2, and VREAD3 may be maintained.

In some implementations, through operation S110 to operation S150, a point in time when the levels of the enable signals EN1, EN2, and EN3 are changed may be (e.g., substantially) identical to a point in time when the level of the switch input voltage SIV is changed. For example, in operation S120, a point in time when the first enable signal EN1 and the third enable signal EN3 are changed to the low level may be (e.g., substantially) identical to a point in time when the voltage regulator circuit 220 applies the second switch input voltage SIV2 (in response to the reference voltage generation circuit 210 of FIG. 5 applying the second reference voltage VREF2). For another example, in operation S110, the point in time when the first enable signal EN1 and the third enable signal EN3 are changed to the low level may be (e.g., substantially) identical to the point in time when the voltage regulator circuit 220 applies the second switch input voltage SIV2 (in response to that the reference voltage generation circuit 210 of FIG. 5 applies the second reference voltage VREF2).

In FIG. 7, the switch input voltage SIV may be changed in response to the plurality of reference voltages VREF1 to VREF3 changing. For example, levels of switch input voltages may be changed based on changing reference voltages (e.g., the plurality of reference voltages VREF1 to VREF3 of FIG. 5) to be applied to one voltage regulator circuit 220. In operation S120, operation S130, and operation S140 of FIG. 7, the description is given based on the case where the voltages of the word line groups WG1, WG2, and WG3 reach target levels, but the voltage control is not limited thereto. It should be understood that some implementations in which levels of at least some of the word line groups WG1, WG2, and WG3 fail to reach the corresponding target levels through operation S120 to operation S140 also belong to the scope and spirit of the present disclosure (for example, in this case, the unselected read voltage generator 200 may further iterate operation S120 to operation S140 once or more).

The operation of the unselected read voltage generator 200 described with reference to FIG. 7 is provided as an example, and the operations of unselected read voltage generators are not limited thereto. For example, it should be understood that some implementations in which at least some of the above operations are omitted, some implementations in which at least some of the above operations are further performed, some implementations in which the order of performing at least some of the above operations is changed, and some implementations in which at least some or all of the above operations are performed to overlap each other, also belong to the scope and spirit of the present disclosure. For example, the unselected read voltage generator 200 may apply the corresponding unselected read voltages VREAD1, VREAD2, and VREAD3 to the word line groups WG1, WG2, and WG3, by omitting operation S110, omitting operation S150, performing operation S120 to operation S140 in an arbitrary order, or iterating operation S120 to operation S140 once or more, or through a combination thereof.

In FIG. 7, the description is given based on an example in which the voltage level of each of the word line groups WG1, WG2, and WG3 is increased or pulled up, but the voltage levels are not limited thereto. For example, voltage levels of at least some of the word line groups WG1, WG2, and WG3 may be decreased or pulled down such that the unselected read voltages VREAD1, VREAD2, and VREAD3 are applied. In FIG. 7, the description is given based on the case where three unselected read voltages are applied to three word line groups, but this is provided as an example. It should be understood that some implementations in which the number of word line groups is any other value except for a value of 3 or some implementations in which the number of unselected read voltages is any other value except for a value of 3 also belong to the scope and spirit of the present disclosure.

Below, how internal signals of the unselected read voltage generator 200 change over time will be described in detail with reference to FIGS. 8 to 10.

FIG. 8 is a timing diagram illustrating an example of an operation of an unselected read voltage generator of FIGS. 5 and 6 over time. Referring to FIG. 8, how the plurality of reference voltages VREF, the enable signals EN1, EN2, and EN3, and word line group voltage levels VWG1, VWG2, and VWG3 change over time is illustrated. The first word line group voltage level VWG1 may be the voltage level of the first word line group WG1, the second word line group voltage level VWG2 may be the voltage level of the second word line group WG2, and the third word line group voltage level VWG3 may be the voltage level of the third word line group WG3.

In response to changes of the plurality of reference voltages VREF, the voltage regulator circuit 220 of FIG. 5 may change the switch input voltages SIV so as to be provided to the switch circuit 230. In FIG. 8, the description will be given based on the changes of the plurality of reference voltages VREF, but it should be understood that the switch input voltages SIV1 and SIV2 are changed in response to the changes of the plurality of reference voltages VREF.

Before a first time point t1, all the word line group voltage levels VWG1, VWG2, and VWG3 may be an initial voltage V0. The levels of the plurality of reference voltages VREF may be “0”, and all the enable signals EN1, EN2, and EN3 may be at the low level. Levels of signals before the first time point t1 are provided as an example, and the signal levels over this interval are not limited thereto.

A period from t1 to t2 may be a level merge period, and all the word line group voltage levels VWG1, VWG2, and VWG3 may simultaneously increase. At the first time point t1, the reference voltage generation circuit 210 may output the first reference voltage VREF1 among the plurality of reference voltages VREF. In some implementations, during the level merge period t1 to t2, the reference voltage generation circuit 210 of FIG. 5 may generate the first reference voltage VREF1, based on the trimcode corresponding to the first reference voltage VREF1 and the clock signal CLK. In some implementations, the first reference voltage VREF1 may be correspond to the first unselected read voltage VREAD1. For example, the level of the first unselected read voltage VREAD1 may be identical or similar to the level of the first switch input voltage SIV1, and the first switch input voltage SIV1 may be a voltage obtained by regulating the first reference voltage VREF1 (e.g., by the voltage regulator circuit 220).

In the level merge period t1 to t2, all the enable signals EN1, EN2, and EN3 may be at the high level. In some implementations, at the first time point t1, the enable signals EN1, EN2, and EN3 may transition from the low level to the high level. In the level merge period t1 to t2, the word line group voltage levels VWG1, VWG2, and VWG3 may be simultaneously increased or pulled up. In some implementations, the word line group voltage levels VWG1, VWG2, and VWG3 may be increased or pulled up to the first unselected read voltage VREAD1 in the level merge period t1 to t2. For example, the word line group voltage levels VWG1, VWG2, and VWG3 may be increased or pulled up to the first unselected read voltage VREAD1 before the second time point t2.

In FIG. 8, the description is given based on the case where the word line group voltage levels VWG1, VWG2, and VWG3 are increased or pulled up to the first unselected read voltage VREAD1 in the level merge period t1 to t2, which is provided as an example, and the scope and spirit of the present disclosure is not limited thereto. For example, it should be understood that some implementations in which the word line group voltage levels VWG1, VWG2, and VWG3 are increased or pulled up to any other level in the level merge period t1 to t2 also belong to the scope and spirit of the present disclosure.

A period t2 to t7 may be a level split period. A period from t2 to t5 may be a first level split period t2 to t5, a period from t5 to t6 may be a second level split period t5 to t6, and a period from t6 to t7 may be a third level split period t6 to t7. The word line group voltage levels VWG1, VWG2, and VWG3 may be changed to have different levels in the first to third level split periods.

At the second time point t2, the second enable signal EN2 and the third enable signal EN3 may transition to the low level. In response to the second enable signal EN2 transitioning to the low level, the second switch circuit 320 may open the connection between the switch input voltage SIV and the second word line group WG2. Likewise, in response to that third enable signal EN3 transitioning to the low level, the third switch circuit 330 may open the connection between the switch input voltage SIV and the third word line group WG3. The second word line group WG2 and the third word line group WG3 may be floated, and the second word line group voltage level VWG2 and the third word line group voltage level VWG3 may maintain the first unselected read voltage VREAD1.

At the second time point t2, the reference voltage generation circuit 210 may maintain the first reference voltage VREF1 output at the first time point t1 from among the plurality of reference voltages VREF, and the first enable signal EN1 may be maintained at the high level. In a period from t2 to t3, the first word line group voltage level VWG1 may maintain the first unselected read voltage VREAD1 or may be increased or pulled up to the first unselected read voltage VREAD1. In FIG. 8, the description is given based on the case where the second enable signal EN2 and the third enable signal EN3 are at the low level in the period from t2 to t3, but the voltage level is not limited thereto. For example, it should be understood that some implementations in which the second enable signal EN2 or the third enable signal EN3 maintains the high level also belong to the scope and spirit of the present disclosure.

At the third time point t3, the reference voltage generation circuit 210 may maintain the second reference voltage VREF2 among the plurality of reference voltages VREF or may change a level of a reference voltage to be output, to the level of the second reference voltage VREF2. In some implementations, in a period from t3 to t4, the reference voltage generation circuit 210 of FIG. 5 may generate the second reference voltage VREF2, based on the trimcode corresponding to the second reference voltage VREF2 and the clock signal CLK. In some implementations, the second reference voltage VREF2 may correspond to the second unselected read voltage VREAD2. For example, the level of the second unselected read voltage VREAD2 may be identical or similar to the level of the second switch input voltage SIV2, and the second switch input voltage SIV2 may be a voltage obtained by regulating the second reference voltage VREF2 (e.g., by the voltage regulator circuit 220).

At the third time point t3, the first enable signal EN1 may transition to the low level. In response to that first enable signal EN1 transitioning to the low level, the first switch circuit 310 may open the connection between the switch input voltage SIV and the first word line group WG1. The first word line group WG1 may be floated, and the first word line group voltage level VWG1 may maintain the first unselected read voltage VREAD1. At the third time point t3, the third enable signal EN3 may maintain the low level. Accordingly, the third word line group WG3 may be floated, and the third word line group voltage level VWG3 may maintain the first unselected read voltage VREAD1.

At the third time point t3, the second enable signal EN2 may transition to the high level. In response to the second enable signal EN2 transitioning to the high level, the second switch circuit 320 may connect the switch input voltage SIV and the second word line group WG2. The level of the second word line group voltage level VWG2 may be increased or pulled up based on the connection with the switch input voltage SIV (or the second switch input voltage SIV2). The level of the second word line group voltage level VWG2 may be increased or pulled up until the fourth time point t4, and at the fourth time point t4, the level of the second word line group voltage level VWG2 may have a level between the first unselected read voltage VREAD1 and the second unselected read voltage VREAD2.

At the fourth time point t4, the reference voltage generation circuit 210 may maintain the third reference voltage VREF3 among the plurality of reference voltages VREF or may change a level of a reference voltage to be output, to the level of the third reference voltage VREF3. In some implementations, in a period from t4 to t5, the reference voltage generation circuit 210 of FIG. 5 may generate the third reference voltage VREF3, based on the trimcode corresponding to the third reference voltage VREF3 and the clock signal CLK. In some implementations, the third reference voltage VREF3 may correspond to the third unselected read voltage VREAD3. For example, the level of the third unselected read voltage VREAD3 may be identical or similar to the level of the third switch input voltage SIV3, and the third switch input voltage SIV3 may be a voltage obtained by regulating the third reference voltage VREF3 (e.g., by the voltage regulator circuit 220).

At the fourth time point t4, the second enable signal EN2 may transition to the low level. In response to the second enable signal EN2 transitioning to the low level, the second switch circuit 320 may open the connection between the switch input voltage SIV and the second word line group WG2. The second word line group WG2 may be floated, and the second word line group voltage level VWG2 may maintain the level at the fourth time point t4. At the fourth time point t4, the first enable signal EN1 may maintain the low level. Accordingly, the first word line group WG1 may maintain the floating state, and the first word line group voltage level VWG1 may maintain the first unselected read voltage VREAD1.

At the fourth time point t4, the third enable signal EN3 may transition to the high level. In response to the third enable signal EN3 transitioning to the high level, the third switch circuit 330 may connect the switch input voltage SIV and the third word line group WG3 (or the third word line group voltage level VWG3). The level of the third word line group voltage level VWG3 may be increased or pulled up based on the connection with the switch input voltage SIV (or the third switch input voltage SIV3). The level of the third word line group voltage level VWG3 may be increased or pulled up until the fifth time point t5, and at the fifth time point t5, the level of the third word line group voltage level VWG3 may have a level between the first unselected read voltage VREAD1 and the third unselected read voltage VREAD3 (for example, VREAD2).

Through the operation of the first level split period t2 to t5, the unselected read voltage generator 200 may be increased or pulled up by splitting the levels of the first word line group voltage level VWG1, the second word line group voltage level VWG2, and the third word line group voltage level VWG3. In a period from t5 to t6, the unselected read voltage generator 200 may perform an operation(s) identical or similar to the operation(s) in the period from t2 to t5. For example, at the sixth time point t6, each of the word line group voltage levels VWG1, VWG2, and VWG3 may have a target voltage level. For example, the level of the first word line group voltage level VWG1 may be the first unselected read voltage VREAD1 at the sixth time point t6, the level of the second word line group voltage level VWG2 may be the second unselected read voltage VREAD2 at the sixth time point t6, and the level of the third word line group voltage level VWG3 may be the third unselected read voltage VREAD3 at the sixth time point t6. In the period from t5 to t6, by repeating the VREF and EN changes of t2 to t5, VGW1 may be maintained constant at VREAD1; VWG2 may be increased from a level between VREAD1 and VREAD2 to VREAD2; and VWG3 may be increased from a level between VREAD1 and VREAD3 (e.g., VREAD2) to VREAD3.

In some implementations, in the third level split period t6 to t7, the unselected read voltage generator 200 may perform an operation(s) identical or similar to the operation(s) in the period from t2 to t5 or may perform an operation(s) identical or similar to the operation(s) in the period from t5 to t6. The word line group voltage levels VWG1, VWG2, and VWG3 may maintain the target levels, based on the operation of the third level split period t6 to t7. In some implementations, after the seventh time point t7, all the enable signals EN1, EN2, and EN3 may be at the low level. In this case, all the word line groups WG1, WG2, and WG3 may be floated and may maintain the levels at the seventh time point t7.

In some implementations, even after the seventh time point t7, the unselected read voltage generator 200 may iterate an operation(s) identical or similar to the operation(s) in the period from t2 to t5. In this case, even after the seventh time point t7, the word line group voltage levels VWG1, VWG2, and VWG3 may maintain the levels at the seventh time point t7. Even after the seventh time point t7, the unselected read voltage generator 200 may iterate an operation(s) identical or similar to the operation(s) in the first level split period t2 to t5 and thus may maintain the levels of the word line group voltage levels VWG1, VWG2, and VWG3 at the unselected read voltages VREAD1, VREAD2, and VREAD3 more stably. In some implementations, after the seventh time point t7, the unselected read voltage generator 200 may change the word line group voltage levels VWG1, VWG2, and VWG3 to the initial voltage V0 at a point in time when the read operation of the non-volatile memory device 100 is terminated or before and after the point in time (in this case, the enable signals EN1, EN2, and EN3 may transition to the low level or may have an arbitrary state).

In FIG. 8, description is given based on the case where the unselected read voltage generator 200 iterates an operation(s) identical or similar to the operation(s) in the first level split period three times, which is provided as an example, and the number or presence of iterations is not limited thereto. In some implementations, the unselected read voltage generator 200 may perform an operation(s) identical or similar to the operation(s) in the first level split period “n” times, and “n” may be an integer of 1 or more (that is, it should be understood that some implementations in which the unselected read voltage generator 200 does not iterate an operation(s) in a level split period also belong to the scope and spirit of the present disclosure). For example, the unselected read voltage generator 200 may perform the operation in the level merge period and the level split period once and may apply the unselected read voltages VREAD1, VREAD2, and VREAD3 to the word line groups WG1, WG2, and WG3. For another example, the unselected read voltage generator 200 may perform the operation in the level merge period and may then perform the operations in the level split period two times, and thus, the unselected read voltages VREAD1, VREAD2, and VREAD3 may be applied to the word line groups WG1, WG2, and WG3. In some implementations, even after the voltage levels of the word line groups WG1, WG2, and WG3 reach the target levels, the unselected read voltage generator 200 may further perform an operation(s) identical or similar to the operation(s) in the level split period once or more.

The description is given based on the case where, in all the level split periods, the unselected read voltage generator 200 increases or pulls up the levels of the word line group voltage levels VWG1, VWG2, and VWG3 in the same order and floats the word line groups WG1, WG2, and WG3 in the same order, but the ordering is not limited thereto. For example, in the second level split period t5 to t6, the unselected read voltage generator 200 may increase or pull up the level of the second word line group voltage level VWG2 and may float the second word line group WG2, may then increase or pull up the level of the first word line group voltage level VWG1 and may float the first word line group WG1, and may lastly increase or pull up the level of the third word line group voltage level VWG3 and may float the third word line group WG3.

In some implementations, in the second level split period or in a subsequent level split period(s), the unselected read voltage generator 200 may omit increasing/pulling up or maintaining at least some of the word line group voltage levels VWG1, VWG2, and VWG3. For example, after the unselected read voltage generator 200 performs the operation(s) in the first level split period of FIG. 8, in the second level split period, the unselected read voltage generator 200 may perform the level increasing or pulling-up operation of the second word line group voltage level VWG2 and the third word line group voltage level VWG3 and may omit the level maintaining (or increasing) operation of the first word line group voltage level VWG1. For FIG. 8, the description is given based on the case in which the word line group voltage levels VWG1, VWG2, and VWG3 are increased or pulled up, but the voltage modification is not limited thereto. It should be understood that some implementations in which the word line group voltage levels VWG1, VWG2, and VWG3 are decreased or pulled down and reach the target levels in all or at least some of the operations of the unselected read voltage generator 200 also belong to the scope and spirit of the present disclosure.

In FIG. 8, the description is given based on the case where the word line group voltage levels VWG1, VWG2, and VWG3 maintain the corresponding levels (e.g., accurately) when all the word line group voltage levels VWG1, VWG2, and VWG3 are floated, but the scope and spirit of the present disclosure is not limited thereto. For example, in some implementations, the corresponding levels are not fully maintained. In FIG. 8, the description is given based on the case where each of the number of word line group voltage levels VWG1, VWG2, and VWG3 is three and the number of target levels of the word line group voltage levels VWG1, VWG2, and VWG3 is three, but the numbers are not limited thereto. It should be understood that some implementations in which the number of pass voltages is any other value except for a value of 3, some implementations in which the number of target levels of the pass voltages is any other value except for a value of 3, or some implementations in which the number of pass voltages is different from the number of target levels of the pass voltages also belong to the scope and spirit of the present disclosure. The form (e.g., the rough shape of a graph) or aspect of change of the plurality of reference voltages VREF or the word line group voltage levels VWG1, VWG2, and VWG3 described with reference to FIG. 8 is provided as an example, and voltage changes are not limited thereto. It should be understood that some implementations in which a plurality of reference voltages or word line group voltage levels change to be different from the plurality of reference voltages VREF or the word line group voltage levels VWG1, VWG2, and VWG3 illustrated in FIG. 8 and described with reference to FIG. 8 also belong to the scope and spirit of the present disclosure. For example, it should be understood that some implementations in which the word line group voltage levels VWG1, VWG2, and VWG3 reach the target levels in the first level split period and maintain the target levels in the second level split period and the third level split period also belong to the scope and spirit of the present disclosure.

Time intervals between time points illustrated in FIG. 8 are for indicating the order of operations and should not be understood as indicating a time necessary for the operation(s). For example, a time interval between the second time point t2 and the third time point t3 may be different from a time interval between the third time point t3 and the fourth time point t4.

The unselected read voltage generator 200 may generate a plurality of unselected read voltages based on the operations described with reference to FIG. 8 and one voltage regulator, thus reducing the area and power consumption of the unselected read voltage generator 200. The unselected read voltage generator 200 may generate a plurality of unselected read voltages by using voltage regulators, the number of which is less than the number of unselected read voltages to be generated, thus reducing the circuit area and power consumption of the unselected read voltage generator 200.

The unselected read voltage generator 200 may stably provide the unselected read voltages VREAD1, VREAD2, and VREAD3 respectively corresponding to the word line groups WG1, WG2, and WG3, based on the operations described with reference to FIG. 8. Based on the repetition of an operation(s) identical or similar to the operation(s) in the first level split period, the unselected read voltage generator 200 may reduce or remove the coupling effect of an adjacent word line due to the floating and may stably maintain voltages being applied to unselected word lines. Based on the repetition of an operation(s) identical or similar to the operation(s) in the first level split period, the unselected read voltage generator 200 may allow the unselected read voltages VREAD1, VREAD2, and VREAD3 to be stably applied to gates of memory cells (connected to unselected word lines) of a cell string distant from the unselected read voltage generator 200.

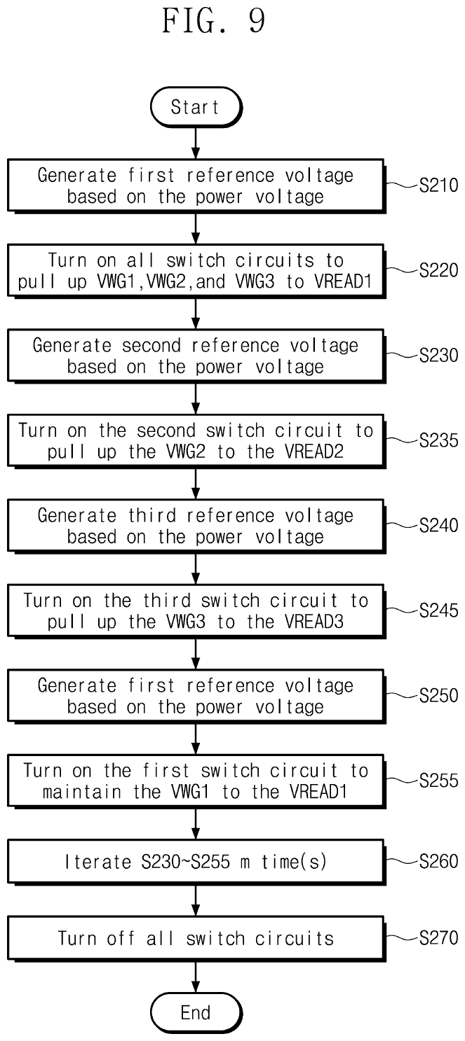

FIG. 9 is a flowchart illustrating an operation method of an unselected read voltage generator according to some implementations of the present disclosure. An operation method of the unselected read voltage generator 200 according to some implementations of the present disclosure will be described with reference to FIGS. 4 to 9.

In operation S210, the unselected read voltage generator 200 may generate the first reference voltage VREF1, based on the power supply voltage VCC. In some implementations, the unselected read voltage generator 200 may generate the first reference voltage VREF1 or the plurality of reference voltages VREF having a first reference voltage level, through the reference voltage generation circuit 210. In operation S220, the unselected read voltage generator 200 may turn on all switch circuits and may pull up levels of the word line group voltage levels VWG1, VWG2, and VWG3 to the first unselected read voltage VREAD1. For example, based on the operation(s) identical or similar to the operation(s) in the level merge period t1 to t2 of FIG. 8, the unselected read voltage generator 200 may pull up the word line group voltage levels VWG1, VWG2, and VWG3 to the first unselected read voltage VREAD1.

In operation S230, the unselected read voltage generator 200 may generate the second reference voltage VREF2, based on the power supply voltage VCC. In some implementations, through the reference voltage generation circuit 210, the unselected read voltage generator 200 may generate the second reference voltage VREF2 or may change a reference voltage to have the level of the second reference voltage VREF2 among the plurality of reference voltages VREF.

In operation S235, the unselected read voltage generator 200 may maintain the second switch circuit 320 in the turn-on state and may pull up the level of the second word line group voltage level VWG2 to the second unselected read voltage VREAD2. In this case, the first switch circuit 310 and the third switch circuit 330 may be in the turn-off state. In some implementations, in operation S235, the level of the second word line group voltage level VWG2 may fail to reach the second unselected read voltage VREAD2 (e.g., may be less than VREAD2). For example, the unselected read voltage generator 200 may perform operation S235 to be identical or similar to the operation(s) from the third time point t3 to the fourth time point t4 of FIG. 8.

In operation S240, the unselected read voltage generator 200 may generate the third reference voltage VREF3, based on the power supply voltage VCC. In some implementations, through the reference voltage generation circuit 210, the unselected read voltage generator 200 may generate the third reference voltage VREF3 or may change a reference voltage to have the level of the third reference voltage VREF3 among the plurality of reference voltages VREF.

In operation S245, the unselected read voltage generator 200 may maintain the third switch circuit 330 in the turn-on state and may pull up the level of the third word line group voltage level VWG3 to the third unselected read voltage VREAD3. In this case, the first switch circuit 310 and the second switch circuit 320 may be in the turn-off state. In some implementations, in operation S245, the level of the third word line group voltage level VWG3 may fail to reach the third unselected read voltage VREAD3 (e.g., may be less than VREAD3). For example, the unselected read voltage generator 200 may perform operation S245 to be identical or similar to the operation(s) from the fourth time point t4 to the fifth time point t5 of FIG. 8.

In operation S250, the unselected read voltage generator 200 may generate the first reference voltage VREF1, based on the power supply voltage VCC. In some implementations, through the reference voltage generation circuit 210, the unselected read voltage generator 200 may generate the first reference voltage VREF1 or may change a reference voltage to have the level of the first reference voltage VREF1 among the plurality of reference voltages VREF.

In operation S255, the unselected read voltage generator 200 may maintain the first switch circuit 310 in the turn-on state and may pull up the level of the first word line group voltage level VWG1 to the first unselected read voltage VREAD1. In this case, the second switch circuit 320 and the third switch circuit 330 may be in the turn-off state. For example, the unselected read voltage generator 200 may perform operation S255 to be identical or similar to the operation(s) from the second time point t2 to the third time point t3 of FIG. 8.

In operation S260, the unselected read voltage generator 200 may iterate operation S230 to operation S255. In some implementations, the unselected read voltage generator 200 may iterate an operation(s) identical or similar to the operation(s) in operation S230 to operation S255. For example, referring to FIG. 8, the unselected read voltage generator 200 may perform an operation(s) identical or similar to the operation(s) in the second level split period t5 to t6 or the third level split period t6 to t7. In some implementations, the unselected read voltage generator 200 may iterate operation S230 to operation S255 “m” times, and “m” may be an integer of 1 or more.

In operation S270, the unselected read voltage generator 200 may turn off all the switch circuits. For example, like the description given for after the seventh time point t7 of FIG. 8, the unselected read voltage generator 200 may change the enable signals EN1, EN2, and EN3 to the low level and may turn off all the switch circuits 310, 320, and 330.

In FIG. 9, the description is given for a case where the unselected read voltage generator 200 proceeds to operation S270 after operation S260, but the operations are not limited thereto. In some implementations, the unselected read voltage generator 200 may perform operation S260, and may then iterate the operation(s) in operation S230 to operation S255 identically or similarly, and may then terminate the operation (e.g., in synchronization with the termination of the read operation of the non-volatile memory device 100). It should be understood that some implementations in which the unselected read voltage generator 200 omits at least some of the operations of FIG. 9, some implementations in which the order of performing at least some of the operations of FIG. 9 is changed, or a combination thereof also belong to the scope and spirit of the present disclosure. For example, the unselected read voltage generator 200 may omit operation S260 and may proceed to operation S270 after operation S255. For another example, the unselected read voltage generator 200 may omit operation S210 and operation S220, may perform operations identical or similar to those in operation S230 to operation S255 such that the unselected read voltages VREAD1, VREAD2, and VREAD3 may be applied to the word line groups WG1, WG2, and WG3. For another example, the unselected read voltage generator 200 may perform the pull-up operation of the word line group voltage levels VWG1, VWG2, and VWG3 in order of operation S240, operation S245, operation S230, operation S235, operation S250, and operation S255. In some implementations, the unselected read voltage generator 200 may perform operation S260 to be different in order from operation S230 to operation S255. In some implementations, the unselected read voltage generator 200 may perform at least some of the iterations of operation S260 in different orders. FIG. 9 is described based on a case in which the unselected read voltage generator 200 pulls up the word line group voltage levels VWG1, VWG2, and VWG3, but the voltage control is not limited thereto. It should be understood that some implementations in which the word line group voltage levels VWG1, VWG2, and VWG3 are pulled down in some of the above operations also belong to the scope and spirit of the present disclosure.

FIG. 10 is a timing diagram illustrating an example of an operation of an unselected read voltage generator of FIGS. 5 and 6 over time, according to some implementations of the present disclosure.

A period from t11 to t12 may be a first level split period t11 to t12. In some implementations, the unselected read voltage generator 200 may increase the word line group voltage levels VWG1, VWG2, and VWG3 independently of each other. For example, the unselected read voltage generator 200 may perform an operation(s) in the first level split period t11 to t12 to be identical to similar to the operation(s) in the first level split period t2 to t5 of FIG. 8. In some implementations, the word line group voltage levels VWG1, VWG2, and VWG3 may fail to reach the target levels in the first level split period t11 to t12. For example, at t12, VWG1, VWG2, and/or VWG3 may be less than VREAD1, VREAD2, and/or VREAD3, respectively.

A period from t12 to t13 may be a second level split period t12 to t13. In some implementations, the unselected read voltage generator 200 may increase the word line group voltage levels VWG1, VWG2, and VWG3 independently of each other. For example, the unselected read voltage generator 200 may perform an operation(s) in the second level split period t12 to t13 to be identical to similar to the operation(s) in the first level split period t2 to t5 or the second level split period t5 to t6 of FIG. 8. In some implementations, the word line group voltage levels VWG1, VWG2, and VWG3 may fail to reach the target levels in the second level split period t12 to t13. For example, at t13, VWG1, VWG2, and/or VWG3 may be less than VREAD1, VREAD2, and/or VREAD3, respectively, and may be greater than their respective values at t12.

A period from t13 to t14 may be a third level split period t13 to t14. In some implementations, the unselected read voltage generator 200 may increase the word line group voltage levels VWG1, VWG2, and VWG3 independently of each other. For example, the unselected read voltage generator 200 may perform an operation(s) in the third level split period t13 to t14 to be identical to similar to the operation(s) in the first level split period t2 to t5, the second level split period t5 to t6, or the third level split period t6 to t7 of FIG. 8. In some implementations, the word line group voltage levels VWG1, VWG2, and VWG3 may reach the target levels at the fourteenth time point t14. For example, the level of the first word line group voltage level VWG1 may be the first unselected read voltage VREAD1 at the fourteenth time point t14, the level of the second word line group voltage level VWG2 may be the second unselected read voltage VREAD2 at the fourteenth time point t14, and the level of the third word line group voltage level VWG3 may be the third unselected read voltage VREAD3 at the fourteenth time point t14.

In some implementations, after the fourteenth time point t14, the unselected read voltage generator 200 may maintain all the enable signals EN1, EN2, and EN3 at the low level and may turn off all the switch circuits 310, 320, and 330. In this case, the word line groups WG1, WG2, and WG3 may be in the floating state, and the levels of the word line group voltage levels VWG1, VWG2, and VWG3 may respectively correspond to the first unselected read voltage VREAD1, the second word line group voltage level VWG2, and the third unselected read voltage VREAD3.

In some implementations, after the fourteenth time point t14, the unselected read voltage generator 200 may iterate operation(s) identical or similar to the operation(s) in the level split periods t11 to t12, t12 to t13, and t13 to t14. In this case, even after the fourteenth time point t14, the word line group voltage levels VWG1, VWG2, and VWG3 may maintain the levels at the fourteenth time point t14. Even after the fourteenth time point t14, the unselected read voltage generator 200 may iterate an operation(s) identical or similar to the operation(s) in the first level split period t11 to t12 and thus may maintain the word line group voltage levels VWG1, VWG2, and VWG3 at the unselected read voltages VREAD1, VREAD2, and VREAD3 more stably. In some implementations, after the fourteenth time point t14, the unselected read voltage generator 200 may change the word line group voltage levels VWG1, VWG2, and VWG3 to the initial voltage V0 at a point in time when the read operation of the non-volatile memory device 100 is terminated or before and after the point in time (in this case, the enable signals EN1, EN2, and EN3 may transition to the low level or may have an arbitrary state).

In FIG. 10, the description is given based on the case where the unselected read voltage generator 200 iterates the operation(s) in the level split period three times, but the number of iterations is not limited thereto. For example, the unselected read voltage generator 200 may perform an operation(s) identical or similar to the operation(s) in the first level split period once and may apply the unselected read voltages VREAD1, VREAD2, and VREAD3 respectively corresponding the word line groups WG1, WG2, and WG3. For another example, the unselected read voltage generator 200 may perform an operation(s) identical or similar to the operation(s) in the first level split period two times and may apply the unselected read voltages VREAD1, VREAD2, and VREAD3 respectively corresponding the word line groups WG1, WG2, and WG3. In some implementations, even after the word line group voltage levels VWG1, VWG2, and VWG3 reach the target levels, the unselected read voltage generator 200 may further perform the operation(s) identical or similar to the operation(s) in the first level split period once or more.

In FIG. 10, the description is given based on the case where the unselected read voltage generator 200 performs the same operations in the first level split period t11 to t12, the second level split period t12 to t13, and the third level split period t13 to t14. However, it should be understood that some implementations in which at least some of the level split periods t11 to t12, t12 to t13, and t13 to t14 are different from each other also belong to the scope and spirit of the present disclosure. The order of performing at least some of the level split periods t11 to t12, t12 to t13, and t13 to t14 may be different from that illustrated in FIG. 10. For example, in the second level split period t12 to t13, the unselected read voltage generator 200 may increase or pull up the level of the second word line group voltage level VWG2 and may float the second word line group WG2, may then increase or pull up the level of the third word line group voltage level VWG3 and may float the third word line group WG3, and may lastly increase or pull up the level of the first word line group voltage level VWG1 and may float the first word line group WG1.

In FIG. 10, the description is given based on the case where the word line group voltage levels VWG1, VWG2, and VWG3 are increased or pulled up, but the voltage changes are not limited thereto. It should be understood that some implementations in which the unselected read voltage generator 200 decreases or pulls down some or all of the word line group voltage levels VWG1, VWG2, and VWG3 in at least some of the level split periods also belong to the scope and spirit of the present disclosure. In FIG. 10, the degree and timing of changes of the word line group voltage levels VWG1, VWG2, and VWG3 are provided as an example, and voltage changes are not limited thereto. It should be understood that some implementations in which the word line group voltage levels VWG1, VWG2, and VWG3 change to be different from those illustrated in FIG. 10 also belong to the scope and spirit of the present disclosure.

FIG. 11 is a block diagram illustrating a host-storage system according to some implementations of the present disclosure. A host-storage system 1000 may include a host 1100 and a storage device 1200. Also, the storage device 1200 may include the storage controller 1210 and a non-volatile memory device 1220. According to some implementations of the present disclosure, the host 1100 may include a host controller 1110 and a host memory 1120. The host memory 1120 may function as a buffer memory for temporarily storing data to be sent to the storage device 1200 or data sent from the storage device 1200. In some implementations, the non-volatile memory device 1220 may be the non-volatile memory device 100 of FIGS. 1 to 10 or may include the non-volatile memory device 100 of FIGS. 1 to 10.

The storage device 1200 may include storage media configured to store data in response to requests from the host 1100. As an example, the storage device 1200 may include at least one of an SSD, an embedded memory, and a removable external memory. When the storage device 1200 is an SSD, the storage device 1200 may be a device that conforms to an NVMe standard. When the storage device 1200 is an embedded memory or an external memory, the storage device 1200 may be a device that conforms to a UFS standard or an eMMC standard. Each of the host 1100 and the storage device 1200 may generate a packet according to an adopted standard protocol and transmit the packet.

When the NVM 1220 of the storage device 1200 includes a flash memory, the flash memory may include a 2D NAND memory array or a 3D (or vertical) NAND (VNAND) memory array. As another example, the storage device 1200 may include various other kinds of NVMs. For example, the storage device 1200 may include magnetic RAM (MRAM), spin-transfer torque MRAM, conductive bridging RAM (CBRAM), ferroelectric RAM (FRAM), PRAM, RRAM, and various other kinds of memories.

According to some implementations, the host controller 1110 and the host memory 1120 may be implemented as separate semiconductor chips. In some implementations, the host controller 1110 and the host memory 1120 may be integrated in the same semiconductor chip. As an example, the host controller 1110 may be any one of a plurality of modules included in an application processor (AP). The AP may be implemented as a System on Chip (SoC). Further, the host memory 1120 may be an embedded memory included in the AP or an NVM or memory module located outside the AP.

The host controller 1110 may manage an operation of storing data (e.g., write data) of a buffer region of the host memory 1120 in the NVM 1220 or an operation of storing data (e.g., read data) of the NVM 1220 in the buffer region.

The storage controller 1210 may include a host interface 1211, a memory interface 1212, and a CPU 1213. Further, the storage controllers 1210 may further include a flash translation layer (FTL) 1214, a packet manager 1215, a buffer memory 1216, an error correction code (ECC) engine 1217, and an advanced encryption standard (AES) engine 1218. The storage controllers 1210 may further include a working memory (not shown) in which the FTL 1214 is loaded. The CPU 1213 may execute the FTL 1214 to control data write and read operations on the NVM 1220.

The host interface 1211 may transmit and receive packets to and from the host 1100. A packet transmitted from the host 1100 to the host interface 1211 may include a command or data to be written to the NVM 1220. A packet transmitted from the host interface 1211 to the host 1100 may include a response to the command or data read from the NVM 1220. The memory interface 1212 may transmit data to be written to the NVM 1220 to the NVM 1220 or receive data read from the NVM 1220. The memory interface 1212 may be configured to comply with a standard protocol, such as toggle or open NAND flash interface (ONFI).

The FTL 1214 may perform various functions, such as an address mapping operation, a wear-leveling operation, and a garbage collection operation. The address mapping operation may be an operation of converting a logical address received from the host 1100 into a physical address used to actually store data in the NVM 1220. The wear-leveling operation may be a technique for preventing excessive deterioration of a specific block by allowing blocks of the NVM 1220 to be uniformly used. As an example, the wear-leveling operation may be implemented using a firmware technique that balances erase counts of physical blocks. The garbage collection operation may be a technique for ensuring usable capacity in the NVM 1220 by erasing an existing block after copying valid data of the existing block to a new block.

The packet manager 1215 may generate a packet according to a protocol of an interface, which consents to the host 1100, or parse various types of information from the packet received from the host 1100. In addition, the buffer memory 1216 may temporarily store data to be written to the NVM 1220 or data to be read from the NVM 1220. Although the buffer memory 1216 may be a component included in the storage controllers 1210, the buffer memory 1216 may be outside the storage controllers 1210.

The ECC engine 1217 may perform error detection and correction operations on read data read from the NVM 1220. More specifically, the ECC engine 1217 may generate parity bits for write data to be written to the NVM 1220, and the generated parity bits may be stored in the NVM 1220 together with write data. During the reading of data from the NVM 1220, the ECC engine 1217 may correct an error in the read data by using the parity bits read from the NVM 1220 along with the read data, and output error-corrected read data.

The AES engine 1218 may perform at least one of an encryption operation and a decryption operation on data input to the storage controllers 1210 by using a symmetric-key algorithm.

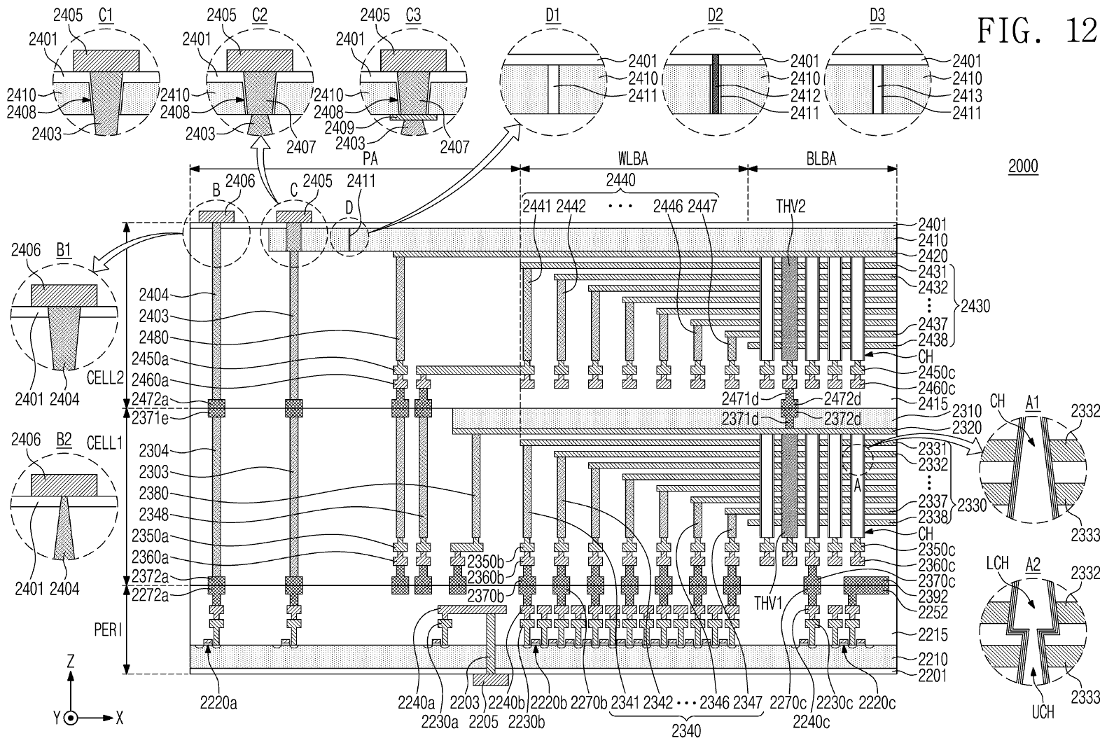

FIG. 12 is a view for describing a memory device 2000 according to some implementations of the present disclosure. In some implementations, the memory device 2000 may be implemented in the form of the non-volatile memory device 100 described with reference to FIGS. 1 to 10 or may correspond to the non-volatile memory device 100.

Referring to FIG. 12, the memory device 2000 may have a chip-to-chip (C2C) structure. Herein, in the C2C structure, after fabricating at least one upper chip including a cell region CELL and at least one lower chip including a peripheral circuit region PERI, respectively, the upper chip and the lower chip may be bonded to each other by a bonding method. As an example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W).

The memory device 200 may include at least one upper chip including a cell region. For example, as illustrated in FIG. 12, the memory device 200 may be implemented to include two upper chips. However, this is illustrative, and the number of upper chips is not limited thereto. In the case in which the memory device 2000 is implemented to include two upper chips, the memory device 2000 may be manufactured by separately manufacturing a first upper chip including a first cell region CELL1, a second upper chip including a second cell region CELL2, and a lower chip including the peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 12, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the memory device 2000 may include an external pad bonding region PA, a word line bonding region WLBA, and a bit line bonding region BLBA.

The peripheral circuit region PERI may include a first substrate 2210 and a plurality of circuit elements 2220a, 2220b, and 2220c formed on the first substrate 2210. In some implementations, the peripheral circuit region PERI may include the voltage generation block 140 described with reference to FIGS. 1 to 10. An interlayer insulating layer 2215 including one or more insulating layers may be provided on the plurality of circuit elements 2220a, 2220b, and 2220c, and a plurality of metal lines connecting the plurality of circuit elements 2220a, 2220b, and 2220c may be provided in the interlayer insulating layer 2215. For example, the plurality of metal lines may include first metal lines 2230a, 2230b, and 2230c connected with the plurality of circuit elements 2220a, 2220b, and 2220c, respectively, and second metal lines 2240a, 2240b, and 2240c formed on the first metal lines 2230a, 2230b, and 2230c. The plurality of metal lines may be formed of at least one of various conductive materials. For example, the first metal lines 2230a, 2230b, and 2230c may be formed of tungsten having a relatively high electrical resistivity, and the second metal lines 2240a, 2240b, and 2240c may be formed of copper having a relatively low electrical resistivity.

In this specification, only the first metal lines 2230a, 2230b, and 2230c and the second metal lines 2240a, 2240b, and 2240c are illustrated and described. However, without being limited thereto, one or more additional metal lines may be further formed on the second metal lines 2240a, 2240b, and 2240c. In this case, the second metal lines 2240a, 2240b, and 2240c may be formed of aluminum. At least some of the additional metal lines formed on the second metal lines 2240a, 2240b, and 2240c may be formed of copper having a lower electrical resistivity than the aluminum of the second metal lines 2240a, 2240b, and 2240c.

The interlayer insulating layer 2215 may be disposed on the first substrate 2210 and may include an insulating material, such as silicon oxide or silicon nitride.

Each of the first and second cell regions CELL1 and CELL2 may include at least one memory block. The first cell region CELL1 may include a second substrate 2310 and a common source line 2320. A plurality of word lines 2331 to 2338 (hereinafter, collectively referred to as “2330”) may be stacked on the second substrate 2310 in a direction (i.e., the Z-axis direction) perpendicular to an upper surface of the second substrate 2310. String selection lines and a ground selection line may be disposed on and under the word lines 2330, and the plurality of word lines 2330 may be disposed between the string selection lines and the ground selection line. Likewise, the second cell region CELL2 may include a third substrate 2410 and a common source line 2420, and a plurality of word lines 2431 to 2438 (hereinafter, collectively referred to as “2430”) may be stacked in a direction (i.e., the Z-axis direction) perpendicular to an upper surface of the third substrate 2410. The second substrate 2310 and the third substrate 2410 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In some implementations, as illustrated in A1, the channel structure CH may be provided in the bit line bonding region BLBA and may extend in the direction perpendicular to the upper surface of the second substrate 2310 to penetrate the word lines 2330, the string selection lines, and the ground selection line. The channel structure CH may include a data storage layer, a channel layer, and a buried insulating layer. The channel layer may be electrically connected with a first metal line 2350c or 2360c and a second metal line 2360c or 2460c in the bit line bonding region BLBA. For example, the second metal line 2360c may be a bit line and may be connected to the channel structure CH through the first metal line 2350c. The bit line 2360c or 2460c may extend in a first direction (i.e., the Y-axis direction) parallel to the upper surface of the second substrate 2310.

In some implementations, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 2310 and may penetrate the common source line 2320 and the lower word lines 2331 and 2332. The lower channel LCH may include a data storage layer, a channel layer, and a buried insulating layer and may be connected with the upper channel UCH. The upper channel UCH may penetrate the upper word lines 2333 to 2338. The upper channel UCH may include a data storage layer, a channel layer, and a buried insulating layer, and the channel layer of the upper channel UCH may be electrically connected with the first metal line 2350c and the second metal line 2360c. As the length of a channel is increased, it may be difficult to form a channel having a constant width due to process reasons. The memory device 2000 according to some implementations of the present disclosure may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 2332 and the word line 2333 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 2331 and 2332 penetrated by the lower channel LCH is smaller than the number of upper word lines 2333 to 2338 penetrated by the upper channel UCH. However, this is illustrative, and the present disclosure is not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 12, the first through-electrode THV1 may penetrate the common source line 2320 and the plurality of word lines 2330. However, this is illustrative, and the first through-electrode THV1 may additionally penetrate the second substrate 2310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected through a first through-metal pattern 2372d and a second through-metal pattern 2472d. The first through-metal pattern 2372d may be formed on a lower side of the first upper chip including the first cell region CELL1, and the second through-metal pattern 2472d may be formed on an upper side of the second upper chip including the second cell region CELL2. The first through-electrode THV1 may be electrically connected with the first metal line 2350c and the second metal line 2360c. A lower VIA 2371d may be formed between the first through-electrode THV1 and the first through-metal pattern 2372d, and an upper VIA 2471d may be formed between the second through-electrode THV2 and the second through-metal pattern 2472d. The first through-metal pattern 2372d and the second through-metal pattern 2472d may be connected by a bonding method.

Furthermore, in the bit line bonding region BLBA, an upper metal pattern 2252 may be formed on the uppermost metal layer of the peripheral circuit region PERI, and an upper metal pattern 2392 having the same shape as the upper metal pattern 2252 may be formed on the uppermost metal layer of the first cell region CELL1. The upper metal pattern 2392 of the first cell region CELL1 and the upper metal pattern 2252 of the peripheral circuit region PERI may be electrically connected to each other by a bonding method. In the bit line bonding region BLBA, the bit line 2360c may be electrically connected with a page buffer included in the peripheral circuit region PERI. For example, some of circuit elements 2220c of the peripheral circuit region PERI may provide a page buffer, and the bit line 2360c may be electrically connected with the circuit elements 2220c providing the page buffer through an upper bonding metal 2370c of the first cell region CELL1 and an upper bonding metal 2270c of the peripheral circuit region PERI.

Continuously referring to FIG. 12, in the word line bonding region WLBA, the word lines 2330 of the first cell region CELL1 may extend in a second direction (an X-axis direction) parallel to the upper surface of the second substrate 2310 and may be connected with a plurality of cell contact plugs 2341 to 2347 (hereinafter, collectively referred to as “2340”). A first metal line 2350b and a second metal line 2360b may be sequentially connected to upper portions of the cell contact plugs 2340 connected to the word lines 2330. In the word line bonding region WLBA, the cell contact plugs 2340 may be connected with the peripheral circuit region PERI through an upper bonding metal 2370b of the first cell region CELL1 and an upper bonding metal 2270b of the peripheral circuit region PERI.

The cell contact plugs 2340 may be electrically connected with a row decoder included in the peripheral circuit region PERI. For example, some of circuit elements 2220b of the peripheral circuit region PERI may provide a row decoder, and the cell contact plugs 2340 may be electrically connected with the circuit elements 2220b providing the row decoder through the upper bonding metal 2370b of the first cell region CELL1 and the upper bonding metal 2270b of the peripheral circuit region PERI. In some implementations, an operating voltage of the circuit elements 2220b that provide the row decoder may differ from an operating voltage of the circuit elements 2220c that provide the page buffer. For example, the operating voltage of the circuit elements 2220c that provide the page buffer may be greater than the operating voltage of the circuit elements 2220b that provide the row decoder.

Likewise, in the word line bonding region WLBA, the word lines 2430 of the second cell region CELL2 may extend in the second direction (the X-axis direction) parallel to the upper surface of the third substrate 2410 and may be connected with a plurality of cell contact plugs 2441 to 2447 (hereinafter, collectively referred to as “2440”). The cell contact plugs 2440 may be connected with the peripheral circuit region PERI through an upper metal pattern of the second cell region CELL2, a lower metal pattern and an upper metal pattern of the first cell region CELL1, and a cell contact plug 2348.

In the word line bonding region WLBA, the upper bonding metal 2370b may be formed in the first cell region CELL1, and the upper bonding metal 2270b may be formed in the peripheral circuit region PERI. The upper bonding metal 2370b of the first cell region CELL1 and the upper bonding metal 2270b of the peripheral circuit region PERI may be electrically connected to each other by a bonding method. The upper bonding metal 2370b and the upper bonding metal 2270b may be formed of aluminum, copper, or tungsten.

In the external pad bonding region PA, a lower metal pattern 2371e may be formed on a lower portion of the first cell region CELL1, and an upper metal pattern 2472a may be formed on an upper portion of the second cell region CELL2. The lower metal pattern 2371e of the first cell region CELL1 and the upper metal pattern 2472a of the second cell region CELL2 may be connected by a bonding method in the external pad bonding region PA. Likewise, an upper metal pattern 2372a may be formed on an upper portion of the first cell region CELL1, and an upper metal pattern 2272a may be formed on an upper portion of the peripheral circuit region PERI. The upper metal pattern 2372a of the first cell region CELL1 and the upper metal pattern 2272a of the peripheral circuit region PERI may be connected to each other by a bonding method.

Common source line contact plugs 2380 and 2480 may be disposed in the external pad bonding region PA. The common source line contact plugs 2380 and 2480 may be formed of a conductive material, such as metal, a metal compound, or doped poly-silicon. The common source line contact plug 2380 of the first cell region CELL1 may be electrically connected with the common source line 2320, and the common source line contact plug 2480 of the second cell region CELL2 may be electrically connected with the common source line 2420. A first metal line 2350a and a second metal line 2360a may be sequentially stacked on an upper portion of the common source line contact plug 2380 of the first cell region CELL1, and a first metal line 2450a and a second metal line 2460a may be sequentially stacked on an upper portion of the common source line contact plug 2480 of the second cell region CELL2.

Input/output pads 2205, 2405, and 2406 may be disposed in the external pad bonding region PA. Referring to FIG. 12, a lower insulating layer 2201 may cover a lower surface of the first substrate 2210, and the first input/output pad 2205 may be formed on the lower insulating layer 2201. The first input/output pad 2205 may be connected with at least one of the plurality of circuit elements 2220a disposed in the peripheral circuit region PERI through a first input/output contact plug 2203 and may be separated from the first substrate 2210 by the lower insulating layer 2201. In addition, a side insulating layer may be disposed between the first input/output contact plug 2203 and the first substrate 2210 and may electrically isolate the first input/output contact plug 2203 from the first substrate 2210.

An upper insulating layer 2401 may be formed on the third substrate 2410 to cover the upper surface of the third substrate 2410. The second input/output pad 2405 and/or the third input/output pad 2406 may be disposed on the upper insulating layer 2401. The second input/output pad 2405 may be connected with at least one of the plurality of circuit elements 2220a disposed in the peripheral circuit region PERI through second input/output contact plugs 2403 and 2303, and the third input/output pad 2406 may be connected with at least one of the plurality of circuit elements 2220a disposed in the peripheral circuit region PERI through third input/output contact plugs 2404 and 2304.

In some implementations, the third substrate 2410 may not be disposed in the regions in which the input/output contact plugs are disposed. For example, as illustrated in B, the third input/output contact plug 2404 may be separated from the third substrate 2410 in a direction parallel to the upper surface of the third substrate 2410, may penetrate an interlayer insulating layer 2415 of the second cell region CELL2, and may be connected to the third input/output pad 2406. In this case, the third input/output contact plug 2404 may be formed through various processes.

For example, as illustrated in B1, the third input/output contact plug 2404 may extend in the third direction (i.e., the Z-axis direction) and may have an increasing diameter toward the upper insulating layer 2401. That is, while the channel structure CH described with reference to A1 has a decreasing diameter toward the upper insulating layer 2401, the third input/output contact plug 2404 may have an increasing diameter toward the upper insulating layer 2401. For example, the third input/output contact plug 2404 may be formed after the second cell region CELL2 and the first cell region CELL1 are coupled by a bonding method.

For example, as illustrated in B2, the third input/output contact plug 2404 may extend in the third direction (i.e., the Z-axis direction) and may have a decreasing diameter toward the upper insulating layer 2401. That is, likewise to the channel structure CH, the third input/output contact plug 2404 may have a decreasing diameter toward the upper insulating layer 2401. For example, the third input/output contact plug 2404 may be formed together with the cell contact plugs 2440 before the second cell region CELL2 and the first cell region CELL1 are coupled by a bonding method.

In some implementations, an input/output contact plug may be disposed to overlap the third substrate 2410. For example, as illustrated in C, the second input/output contact plug 2403 may be formed through the interlayer insulating layer 2415 of the second cell region CELL2 in the third direction (i.e., the Z-axis direction) and may be electrically connected to the second input/output pad 2405 through the third substrate 2410. In this case, a connection structure of the second input/output contact plug 2403 and the second input/output pad 2405 may be implemented in various ways.

For example, as illustrated in C1, an opening 2408 may be formed through the third substrate 2410, and the second input/output contact plug 2403 may be directly connected to the second input/output pad 2405 through the opening 2408 formed in the third substrate 2410. In this case, as illustrated in C1, the second input/output contact plug 2403 may have an increasing diameter toward the second input/output pad 2405. However, this is illustrative, and the second input/output contact plug 2403 may have a decreasing diameter toward the second input/output pad 2405.

For example, as illustrated in C2, the opening 2408 may be formed through the third substrate 2410, and a contact 2407 may be formed in the opening 2408. One end portion of the contact 2407 may be connected to the second input/output pad 2405, and an opposite end portion of the contact 2407 may be connected to the second input/output contact plug 2403. Accordingly, the second input/output contact plug 2403 may be electrically connected to the second input/output pad 2405 through the contact 2407 in the opening 2408. In this case, as illustrated in C2, the contact 2407 may have an increasing diameter toward the second input/output pad 2405, and the second input/output contact plug 2403 may have a decreasing diameter toward the second input/output pad 2405. For example, the second input/output contact plug 2403 may be formed together with the cell contact plugs 2440 before the second cell region CELL2 and the first cell region CELL1 are coupled by a bonding method, and the contact 2407 may be formed after the second cell region CELL2 and the first cell region CELL1 are coupled by the bonding method.

For example, as illustrated in C3, a stopper 2409 may be additionally formed on an upper surface of the opening 2408 of the third substrate 2410. The stopper 2409 may be a metal line formed on the same layer as the common source line 2420. However, this is illustrative, and the stopper 2409 may be a metal line formed on the same layer as at least one of the word lines 2430. The second input/output contact plug 2403 may be electrically connected to the second input/output pad 2405 through the contact 2407 and the stopper 2409.

Meanwhile, similarly to the second and third input/output contact plugs 2403 and 2404 of the second cell region CELL2, the second and third input/output contact plugs 2303 and 2304 of the first cell region CELL1 may have a decreasing diameter toward the lower metal pattern 2371e, or may have an increasing diameter toward the lower metal pattern 2371e.

Meanwhile, in some implementations, a slit 2411 may be formed in the third substrate 2410. For example, the slit 2411 may be formed at any position in the external pad bonding region PA. For example, as illustrated in D, the slit 2411 may be located between the second input/output pad 2405 and the cell contact plugs 2440 when viewed on a plane. However, this is illustrative, and the slit 2411 may be formed such that the second input/output pad 2405 is located between the slit 2411 and the cell contact plugs 2440 when viewed on the plane.

For example, as illustrated in D1, the slit 2411 may be formed through the third substrate 2410. For example, the slit 2411 may be used to prevent the third substrate 2410 from being finely cracked when the opening 2408 is formed. However, this is illustrative, and the slit 2411 may be formed to have a depth ranging from about 60% to about 70% of the thickness of the third substrate 2410.

For example, as illustrated in D2, a conductive material 2412 may be formed in the slit 2411. For example, the conductive material 2412 may be used to discharge a leakage current generated while circuit elements in the external pad bonding region PA are driven. In this case, the conductive material 2412 may be connected to an external ground line.

For example, as illustrated in D3, an insulating material 2413 may be formed in the slit 2411. For example, the insulating material 2413 may be formed to electrically isolate the second input/output pad 2405 and the second input/output contact plug 2403 disposed in the external pad bonding region PA from the word line bonding region WLBA. An influence of a voltage provided through the second input/output pad 2405 on a metal layer disposed on the third substrate 2410 in the word line bonding region WLBA may be interrupted by forming the insulating material 2413 in the slit 2411.

Meanwhile, in some implementations, the first to third input/output pads 2205, 2405, and 2406 may be selectively formed. For example, the memory device 2000 may be implemented to include only the first input/output pad 2205 disposed on the first substrate 2210, only the second input/output pad 2405 disposed on the third substrate 2410, or only the third input/output pad 2406 disposed on the upper insulating layer 2401.

Meanwhile, in some implementations, at least one of the second substrate 2310 of the first cell region CELL1 or the third substrate 2410 of the second cell region CELL2 may be used as a sacrificial substrate and may be completely or partially removed before or after a bonding process. An additional layer may be stacked after the removal of the substrate. For example, the second substrate 2310 of the first cell region CELL1 may be removed before or after the peripheral circuit region PERI and the first cell region CELL1 are bonded to each other, and an insulating layer for covering an upper surface of the common source line 2320 or a conductive layer for connection may be formed. Similarly, the third substrate 2410 of the second cell region CELL2 may be removed before or after the first cell region CELL1 and the second cell region CELL2 are bonded to each other, and the upper insulating layer 2401 for covering an upper surface of the common source line 2420 or a conductive layer for connection may be formed.

In FIG. 12, the description is given based on the case where the peripheral circuit region PERI includes the voltage generation block of FIGS. 1 to 10, but the scope and spirit of the present disclosure is not limited thereto. It should be understood that some implementations in which at least part of the voltage generation block 140 of FIGS. 1 to 10 or the whole voltage generation block 140 of FIGS. 1 to 10 is provided outside the peripheral circuit region PERI also belongs to the scope and spirit of the present disclosure.

According to some implementations of the present disclosure, a non-volatile memory device including a voltage generator capable of generating a plurality of read pass voltages based on one voltage regulator is provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to various examples thereof, it will be apparent to those of ordinary skill in the art that various changes and modifications may be made thereto without departing from the spirit and scope of the present disclosure as set forth in the following claims.

1. An operation method of an unselected read voltage generator included in a non-volatile memory device, the method comprising:
during a first time period, applying a first voltage to a first word line group of a plurality of unselected word lines and to a second word line group of the plurality of unselected word lines, wherein the plurality of unselected word line are included in a plurality of word lines connected to a plurality of memory cells;
during a second time period, floating the first word line group and applying a second voltage to the second word line group; and
during a third time period, floating the second word line group and applying the first voltage to the first word line group,
wherein the unselected read voltage generator includes a voltage regulator configured to generate, based on a first reference voltage, a first input voltage corresponding to the first voltage, and to generate, based on a second reference voltage, a second input voltage corresponding to the second voltage.

2. The method of claim 1, further comprising:
during a fourth time period, floating the first word line group and the second word line group and applying a third voltage to a third word line group,
wherein the voltage regulator is configured to generate, based on a third reference voltage, a third input voltage corresponding to the third voltage.

3. The method of claim 1, further comprising:
in one or more pairs of time periods after the second time period and the third time period, additionally (i) in a first of the pair of time periods, floating the first word line group and applying the second voltage to the second word line group, and (ii) in a second of the pair of time periods, floating the second word line group and applying the first voltage to the first word line group.

4. The method of claim 1, wherein the unselected read voltage generator comprises a switch circuit,
wherein the method comprises providing a first enable signal and a second enable signal to the switch circuit, and
wherein the switch circuit is configured to:
apply the first voltage to the first word line group based on the first enable signal and the first input voltage, and
apply the second voltage to the second word line group based on the second enable signal and the second input voltage.

5. The method of claim 4, wherein the first input voltage and the second input voltage are different levels of a switch input voltage received by the switch circuit, and
wherein the method comprises:
during the third time period, providing the first enable signal with a first level, wherein the switch circuit is configured to apply the switch input voltage to the first word line group in response to the first enable signal having the first level; and
during the second time period, providing the second enable signal with the first level, wherein the switch circuit is configured to apply the switch input voltage to the second word line group in response to the second enable signal having the first level.

6. The method of claim 5, further comprising:
during a fifth time period, floating the first word line group and the second word line group by providing the first enable signal and the second enable signal with a second level different from the first level.

7. The method of claim 4, wherein the switch circuit includes:
a first switch circuit configured to apply the first voltage to the first word line group based on the first enable signal; and
a second switch circuit configured to apply the second voltage to the second word line group based on the second enable signal.

8. The method of claim 7, wherein floating the first word line group comprises providing the first enable signal to the first switch circuit with a first level, and
wherein floating the second word line group comprises providing the second enable signal to the second switch circuit with the first level.

9. The method of claim 1, wherein the unselected read voltage generator further includes a reference voltage generation circuit configured to generate the first reference voltage and the second reference voltage,
wherein the method comprises providing a clock signal to the reference voltage generation circuit, and
wherein the reference voltage generation circuit is configured to output one of the first reference voltage or the second reference voltage based on the clock signal.

10. The method of claim 9, wherein the method comprises providing a power supply voltage, a first trimcode, and a second trimcode to the reference voltage generation circuit, and
wherein the reference voltage generation circuit is configured to:
generate the first reference voltage based on the power supply voltage and the first trimcode;
generate the second reference voltage based on the power supply voltage and the second trimcode; and
provide one of the first reference voltage and the second reference voltage to an input of the voltage regulator based on the clock signal.

11. A non-volatile memory device comprising:
a memory cell array connected to a plurality of word lines, and configured to store data; and
an unselected read voltage generator including a voltage regulator configured to generate a first input voltage corresponding to a first voltage and a second input voltage corresponding to a second voltage,
wherein the unselected read voltage generator is configured to:
during a first time period, apply the first voltage to a plurality of unselected word lines of the plurality of word lines;
during a second time period, float a first word line group of the plurality of unselected word lines and apply the second voltage to a second word line group of the plurality of unselected word lines; and
during a third time period, float the second word line group and apply the first voltage to the first word line group.

12. The non-volatile memory device of claim 11, wherein the unselected read voltage generator is configured to, in one or more pairs of time periods after the second time period and the third time period, additionally (i) in a first of the pair of time periods, floating the first word line group and applying the second voltage to the second word line group, and (ii) in a second of the pair of time periods, floating the second word line group and applying the first voltage to the first word line group.

13. The non-volatile memory device of claim 11, wherein the unselected read voltage generator is configured to, in a fourth time period, float the first word line group and the second word line group and apply a third voltage to a third word line group of the plurality of unselected word lines, and
wherein the voltage regulator is configured to generate a third input voltage corresponding to the third voltage.

14. The non-volatile memory device of claim 11, wherein the unselected read voltage generator is configured to pull up a voltage level of the first word line group to a first unselected read voltage and to pull up a voltage level of the second word line group to a second unselected read voltage.

15. The non-volatile memory device of claim 11, wherein the unselected read voltage generator further includes:
a reference voltage generation circuit configured to generate a first reference voltage and a second reference voltage, based on a power supply voltage; and
a switch circuit, wherein the first input voltage and the second input voltage are different levels of a switch input voltage received by the switch circuit, and wherein the switch circuit is configured to apply the switch input voltage to the first word line group based on a first enable signal and to apply the switch input voltage to the second word line group based on a second enable signal, and
wherein the voltage regulator is configured to generate the first voltage based on the first reference voltage and to generate the second voltage based on the second reference voltage.

16. The non-volatile memory device of claim 15, wherein the switch circuit includes:
a first switch circuit configured to apply the switch input voltage to the first word line group based on the first enable signal; and
a second switch circuit configured to apply the switch input voltage to the second word line group based on the second enable signal.

17. The non-volatile memory device of claim 16, wherein the first switch circuit is configured to provide the switch input voltage to the first word line group in response to the first enable signal having a high level.

18. The non-volatile memory device of claim 16, wherein the switch circuit is configured to:
float the first word line group in response to the first enable signal having a first level; and
float the second word line group in response to the second enable signal having the first level.

19. The non-volatile memory device of claim 11, wherein the unselected read voltage generator is configured to float both the first word line group and the second word line group during a fourth time period.

20. A non-volatile memory device comprising:
a memory cell array connected to a plurality of word lines, and configured to store data; and
an unselected read voltage generator including a voltage regulator configured to generate a first input voltage corresponding to a first voltage and a second input voltage corresponding to a second voltage,
wherein the unselected read voltage generator is configured to:
during a first time period, apply the first voltage to a first word line group of a plurality of unselected word lines and float a second word line group of the plurality of unselected word lines, wherein the plurality of unselected word lines are included in the plurality of word lines; and
during a second time period, float the first word line group and apply the second voltage to the second word line group, and
wherein the voltage regulator is configured to generate the first input voltage based on a first reference voltage and to generate the second input voltage based on a second reference voltage.

21. (canceled)
